(19) United States
(12) Patent Application Publication
(10) Pub. No.: US 2022/0238579 A1
(43) Pub. Date: Jul. 28, 2022

(54) SIMULTANEOUS CAPTURE OF MULTIPLE PHASES FOR IMAGING DEVICES

(71) Applicant: SONY SEMICONDUCTOR SOLUTIONS CORPORATION, Kanagawa (JP)

(72) Inventors: Frederick BRADY, Webster, NY (US); Jeongsoo HAN, Pittsford, NY (US)

(73) Assignee: SONY SEMICONDUCTOR SOLUTIONS CORPORATION, Kanagawa (JP)

(21) Appl. No.: 17/610,252

(22) PCT Filed: May 21, 2020
(86) PCT No.: PCT/IB2020/000392

§ 371 Date: Nov. 10, 2021

Related U.S. Application Data
(60) Provisional application No. 62/850,888, filed on May 21, 2019.

(51) Int. Cl. H01L 27/146

(52) U.S. Cl. CPC H01L 27/14612; H04N 5/232121; H01L 27/14636

(57) ABSTRACT

An imaging device includes a first pixel 51A including a first transfer transistor and a second transfer transistor. The imaging device includes a second pixel 51B adjacent to the first pixel and including a third transfer transistor and a fourth transfer transistor. The imaging device includes a first signal line SL0 coupled to the first transfer transistor that receives a first transfer signal having a first phase of 0 degrees, a second signal line SL180 coupled to the second transfer transistor and that receives a second transfer signal having a second phase of 180 degrees, a third signal line SL90 coupled to the third transfer transistor and that receives a third transfer signal having a third phase of 90 degrees, and a fourth signal line SL270 coupled to the fourth transfer transistor and that receives a fourth transfer signal having a fourth phase of 270 degrees. The imaging device 1 may further include a third pixel 51C, including a fifth transfer transistor and a sixth transfer transistor, adjacent to the second pixel 51B in the first direction, and a fourth pixel 51D, including a seventh transfer transistor and an eighth transfer transistor, adjacent to the third pixel 51C in the first direction. The fifth transfer transistor is coupled to the first signal line SL0, the sixth transfer transistor is coupled to the second signal line SL180, the seventh transfer transistor is coupled to the third signal line SL90, and the eighth transfer transistor is coupled to the fourth signal line SL270. The current path to form a circuit that provides transfer signals to taps A1 and A3 through wirings W1 and W5 is substantially the same. The same is true for signal line pairs SL90/SL90′, SL180/SL180′, and SL270/SL270′. The layout is semi-global in that the current path for connecting each signal line SL to taps A and B is substantially the same for a given phase for each pixel 51, thus allowing for the transfer signals for each phase to reach the taps A and B at a same time.

### FIELD

Example embodiments are directed to imaging devices, imaging apparatuses, and methods for operating the same, and more particularly, to imaging devices, imaging apparatuses, and methods for depth sensing.

### BACKGROUND

Depth sensing has applications in many fields, including object tracking, environment rendering, etc. Some depth sensors employ time-of-flight (ToF) principles to detect a distance to an object or objects within a scene. In general, a ToF depth sensor includes a light source and an imaging device including a plurality of pixels for sensing reflected light. In operation, the light source emits light (e.g., infrared light) toward an object or objects in the scene, and the pixels detect the light reflected from the object or objects. The elapsed time between the initial emission of the light and receipt of the reflected light by each pixel may correspond to a distance from the object or objects. Direct ToF imaging devices may measure the elapsed time itself to calculate the distance while indirect ToF imaging devices may measure the phase delay between the emitted light and the reflected light and translate the phase delay into a distance. The depth values of the pixels are then used by the imaging device to determine a distance to the object or objects, which may be used to create a three dimensional scene of the captured object or objects.

### SUMMARY

Example embodiments relate to imaging devices, imaging apparatuses, and methods thereof that allow for a single pixel to collect a depth signal, allow all phase information to be collected in one frame or two frames, which may reduce motion blur, improve processing time, etc.

According to at least one example embodiment, an imaging device includes a first pixel including a first photoelectric conversion region, a first transfer transistor coupled to the first photoelectric conversion region, and a second transfer transistor coupled to the first photoelectric conversion region. The imaging device includes a second pixel adjacent to the first pixel in a first direction. The second pixel includes a second photoelectric conversion region, a third transfer transistor coupled to the second photoelectric conversion region, and a fourth transfer transistor coupled to the second photoelectric conversion region. The imaging device includes a first signal line coupled to the first transfer transistor and that receives a first transfer signal having a first phase in relation to a phase of a driving signal driving a light source, a second signal line coupled to the second transfer transistor and that receives a second transfer signal having a second phase in relation to the phase of the driving signal, a third signal line coupled to the third transfer transistor and that receives a third transfer signal having a third phase in relation to the phase of the driving signal, and a fourth signal line coupled to the fourth transfer transistor and that receives a fourth transfer signal having a fourth phase in relation to the phase of the driving signal. The first, second, third, and fourth phases are different from one another.

According to at least one example embodiment, the imaging device includes a third pixel adjacent to the second pixel in the first direction. The third pixel includes a third photoelectric conversion region, a fifth transfer transistor coupled to the third photoelectric conversion region, and a sixth transfer transistor coupled to the third photoelectric conversion region. The imaging device includes a fourth pixel adjacent to the third pixel in the first direction. The fourth pixel includes a fourth photoelectric conversion region, a seventh transfer transistor coupled to the fourth photoelectric conversion region, and an eighth transfer transistor coupled to the fourth photoelectric conversion region.

According to at least one example embodiment, the fifth transfer transistor is coupled to the first signal line, the sixth transfer transistor is coupled to the second signal line, the seventh transfer transistor is coupled to the third signal line, and the eighth transfer transistor is coupled to the fourth signal line.

According to at least one example embodiment, the imaging device includes a first wiring that couples the first and fifth transfer transistors to the first signal line, a second wiring that couples the second and sixth transfer transistors to the second signal line, a third wiring that couples the third and seventh transfer transistors to the third signal line, and a fourth wiring that couples the fourth and eighth transfer transistors to the fourth signal line.

According to at least one example embodiment, the first, second, third, and fourth signal lines extend in a second direction perpendicular to the first direction.

According to at least one example embodiment, the first, second, third, and fourth wirings extend in the first direction.

According to at least one example embodiment, in a plan view, each of the first, second, third, and fourth wirings overlaps at least one of the first, second, third, and fourth signal lines.

According to at least one example embodiment, in a plan view, the second and third signal lines are between the first and fourth signal lines.

According to at least one example embodiment, in the plan view, the second and third signal lines are between the second photoelectric conversion region and the third photoelectric conversion region.

According to at least one example embodiment, in the plan view, the first signal line overlaps the first photoelectric conversion region, the second signal line overlaps the second photoelectric conversion region, the third signal line overlaps the third photoelectric conversion region, and the fourth signal line overlaps the fourth photoelectric conversion region.

According to at least one example embodiment, the imaging device includes a fifth signal line coupled to the fifth transfer transistor and that receives the first transfer signal, a sixth signal line coupled to the sixth transfer transistor and that receives the second transfer signal, a seventh signal line coupled to the seventh transfer transistor and that receives the third transfer signal, and an eighth signal line coupled to the eighth transfer transistor and that receives the fourth transfer signal.

According to at least one example embodiment, the imaging device includes a first wiring that couples the first transfer transistor to the first signal line, a second wiring that couples the second transfer transistor to the second signal line, a third wiring that couples the third transfer transistor to the third signal line, and fourth wiring that couples the fourth transfer transistor to the fourth signal line, a fifth wiring that couples the fifth transfer transistor to the fifth signal line, a sixth wiring that couples the sixth transfer transistor to the sixth signal line, a seventh wiring that couples the seventh transfer transistor to the seventh signal line, and an eighth wiring that couples the eighth transfer transistor to the eighth signal line.

According to at least one example embodiment, lengths of the first wiring and the fifth wiring are the same, lengths of the second wiring and the sixth wiring are the same, lengths of the third wiring and the seventh wiring are the same, and lengths of the fourth wiring and the eighth wiring are the same.

According to at least one example embodiment, the first, second, third, fourth, fifth, sixth, seventh, and eighth signal lines extend in a second direction perpendicular to the first direction.

According to at least one example embodiment, in a plan view, the second signal line is between the first photoelectric conversion region and the second photoelectric conversion region, the fourth signal line is between the second photoelectric conversion region and third photoelectric conversion region, the sixth signal line is between the third photoelectric conversion region and the fourth photoelectric conversion region.

According to at least one example embodiment, in the plan view, the first signal line overlaps the first photoelectric conversion region, the third signal line overlaps the second photoelectric conversion region, the fifth signal line overlaps the third photoelectric conversion region, and the seventh signal line overlaps the fourth photoelectric conversion region.

At least one example embodiment is directed to a system including a light source configured to emit a light signal according to a driving signal, and an imaging device including a first pixel and a second pixel. The first pixel includes a first photoelectric conversion region, a first transfer transistor coupled to the first photoelectric conversion region, and a second transfer transistor coupled to the first photoelectric conversion region. The second pixel is adjacent to the first pixel in a first direction and includes a second photoelectric conversion region, a third transfer transistor coupled to the second photoelectric conversion region, and a fourth transfer transistor coupled to the second photoelectric conversion region. The imaging device includes a first signal line coupled to the first transfer transistor and that receives a first transfer signal having a first phase in relation to a phase of the driving signal, a second signal line coupled to the second transfer transistor and that receives a second transfer signal having a second phase in relation to the phase of the driving signal, a third signal line coupled to the third transfer transistor and that receives a third transfer signal having a third phase in relation to the phase of the driving signal, and a fourth signal line coupled to the fourth transfer transistor and that receives a fourth transfer signal having a fourth phase in relation to the phase of the driving signal. The first, second, third, and fourth phases are different from one another.

According to at least one example embodiment, the imaging device includes a third pixel adjacent to the second pixel in the first direction. The third pixel includes a third photoelectric conversion region, a fifth transfer transistor coupled to the third photoelectric conversion region, and a sixth transfer transistor coupled to the third photoelectric conversion region. The imaging device includes a fourth pixel adjacent to the third pixel in the first direction. The fourth pixel includes a fourth photoelectric conversion region, a seventh transfer transistor coupled to the fourth photoelectric conversion region, and

an eighth transfer transistor coupled to the fourth photoelectric conversion region. The fifth transfer transistor is coupled to the first signal line, the sixth transfer transistor is coupled to the second signal line, the seventh transfer transistor is coupled to the third signal line, and the eighth transfer transistor is coupled to the fourth signal line.

According to at least one example embodiment, the imaging device includes a third pixel adjacent to the second pixel in the first direction. The third pixel includes a third photoelectric conversion region, a fifth transfer transistor coupled to the third photoelectric conversion region, and a sixth transfer transistor coupled to the third photoelectric conversion region. The imaging device includes a fourth pixel adjacent to the third pixel in the first direction. The fourth pixel includes a fourth photoelectric conversion region, a seventh transfer transistor coupled to the fourth photoelectric conversion region, a fifth signal line coupled to the fifth transfer transistor and that receives the first transfer signal, a sixth signal line coupled to the sixth transfer transistor and that receives the second transfer signal, a seventh signal line coupled to the seventh transfer transistor and that receives the third transfer signal, and an eighth signal line coupled to the eighth transfer transistor and that receives the fourth transfer signal.

At least one example embodiment is directed to a system including a driver that emits a driving signal, a light source configured to emit light according to the driving signal, and an imaging device including a first pixel and a second pixel. The first pixel includes a first photoelectric conversion region, a first transfer transistor coupled to the first photoelectric conversion region, and a second transfer transistor coupled to the first photoelectric conversion region. The imaging device includes a second pixel adjacent to the first pixel in a first direction. The second pixel includes a second photoelectric conversion region, a third transfer transistor coupled to the second photoelectric conversion region, and a fourth transfer transistor coupled to the second photoelectric conversion region. The imaging device includes a first signal line coupled to the first transfer transistor and that receives a first transfer signal having a first phase in relation to a phase of the driving signal, a second signal line coupled to the second transfer transistor and that receives a second transfer signal having a second phase in relation to the phase of the driving signal, a third signal line coupled to the third transfer transistor and that receives a third transfer signal having a third phase in relation to the phase of the drive signal, and a fourth signal line coupled to the fourth transfer transistor and that receives a fourth transfer signal having a fourth phase in relation to the phase of the driving signal. The first, second, third, and fourth phases are different from one another.

### BRIEF DESCRIPTION OF THE FIGURES

FIG. 1 is a block diagram of an imaging device according to at least one example embodiment.

FIG. 2 illustrates an example schematic of a pixel from FIG. 1.

FIG. 3 illustrates a cross-sectional view of pixels in an imaging device according to at least one example embodiment.

FIG. 4 illustrates a schematic of a pixel array that includes the pixels of FIG. 3.

FIG. 5 illustrates a timing diagram according to at least one example embodiment.

FIG. 6 illustrates a phase arrangement of a pixel array according to at least one example embodiment.

FIG. 7 illustrates a phase arrangement of a pixel array according to at least one example embodiment.

FIG. 8 illustrates a phase arrangement of a pixel array according to at least one example embodiment.

FIG. 9 illustrates a phase arrangement of a pixel array according to at least one example embodiment.

FIG. 10 illustrates a phase arrangement of a pixel array according to at least one example embodiment.

FIG. 11 illustrates a layout for the phase arrangement of FIG. 6 according to at least one example embodiment.

FIG. 12 illustrates a layout for the phase arrangement of FIG. 6 according to at least one example embodiment.

FIG. 13 illustrates a layout for the phase arrangement of FIG. 7 according to at least one example embodiment.

FIG. 14 illustrates a layout for the phase arrangement of FIG. 7 according to at least one example embodiment.

FIG. 15 illustrates a layout for the phase arrangement of FIG. 8 according to at least one example embodiment.

FIG. 16 illustrates a layout for the phase arrangement of FIG. 8 according to at least one example embodiment.

FIG. 17 illustrates a layout for the phase arrangement of FIG. 9 according to at least one example embodiment.

FIG. 18 illustrates a layout for the phase arrangement of FIG. 10 according to at least one example embodiment.

FIG. 19 illustrates a layout for the phase arrangement of FIG. 10 according to at least one example embodiment.

FIG. 21 illustrates a phase arrangement of a pixel array according to at least one example embodiment.

FIG. 22 illustrates a phase arrangement of a pixel array according to at least one example embodiment.

FIG. 23 illustrates a phase arrangement of a pixel array according to at least one example embodiment.

FIG. 24 illustrates a phase arrangement of a pixel array according to at least one example embodiment.

FIG. 25 illustrates a layout for the phase arrangement of FIG. 20 according to at least one example embodiment.

FIG. 26 illustrates a layout for the phase arrangement of FIG. 20 according to at least one example embodiment.

FIG. 27 illustrates a layout for the phase arrangement of FIG. 21 according to at least one example embodiment.

FIG. 28 illustrates a layout for the phase arrangement of FIG. 21 according to at least one example embodiment.

FIG. 29 illustrates a layout for the phase arrangement of FIG. 22 according to at least one example embodiment.

FIG. 30 illustrates a layout for the phase arrangement of FIG. 22 according to at least one example embodiment.

FIG. 31 illustrates a layout for the phase arrangement of FIG. 23 according to at least one example embodiment.

FIG. 32 illustrates a layout for the phase arrangement of FIG. 24 according to at least one example embodiment.

FIG. 33 illustrates a layout for the phase arrangement of FIG. 24 according to at least one example embodiment.

FIG. 34 is a block diagram illustrating an example of a ranging module according to at least one example embodiment.

FIG. 35 is a diagram illustrating use examples of an imaging device according to at least one example embodiment.

### DETAILED DESCRIPTION

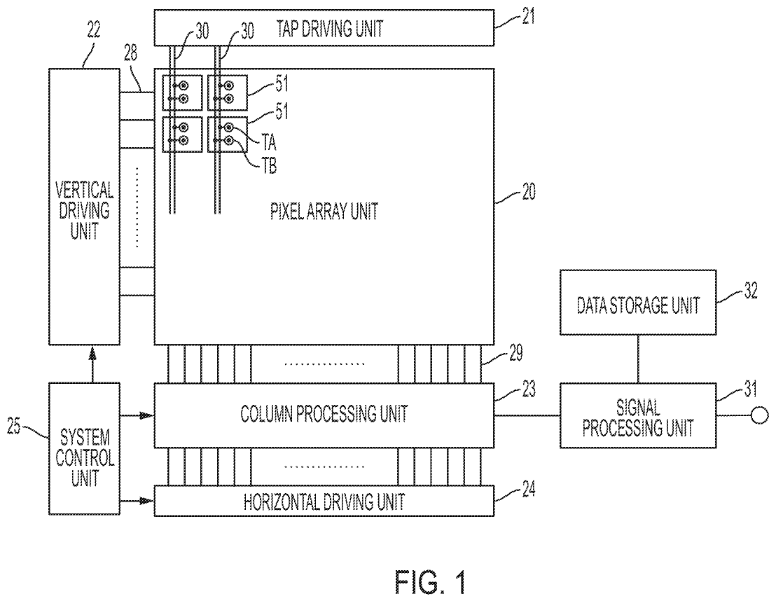

FIG. 1 is a block diagram of an imaging device according to at least one example embodiment.

The imaging device 1 shown in FIG. 1 may be an imaging sensor of a front or rear surface irradiation type, and is provided, for example, in an imaging apparatus having a ranging function (or distance measuring function).

The imaging device 1 has a pixel array unit (or pixel array or pixel section) 20 formed on a semiconductor substrate (not shown) and a peripheral circuit integrated on the same semiconductor substrate the same as the pixel array unit 20. The peripheral circuit includes, for example, a tap driving unit (or tap driver) 21, a vertical driving unit (or vertical driver) 22, a column processing unit (or column processing circuit) 23, a horizontal driving unit (or horizontal driver) 24, and a system control unit (or system controller) 25.

The imaging device element 1 is further provided with a signal processing unit (or signal processor) 31 and a data storage unit (or data storage or memory or computer readable storage medium) 32. Note that the signal processing unit 31 and the data storage unit 32 may be mounted on the same substrate as the imaging device 1 or may be disposed on a substrate separate from the imaging device 1 in the imaging apparatus.

The pixel array unit 20 has a configuration in which pixels 51 that generate charge corresponding to a received light amount and output a signal corresponding to the charge are two-dimensionally disposed in a matrix shape of a row direction and a column direction. That is, the pixel array unit 20 has a plurality of pixels 51 that perform photoelectric conversion on incident light and output a signal corresponding to charge obtained as a result. Here, the row direction refers to an arrangement direction of the pixels 51 in a horizontal direction, and the column direction refers to the arrangement direction of the pixels 51 in a vertical direction. The row direction is a horizontal direction in the figure, and the column direction is a vertical direction in the figure.

The pixel 51 receives light incident from the external environment, for example, infrared light, performs photoelectric conversion on the received light, and outputs a pixel signal according to charge obtained as a result. The pixel 51 may include a first charge collector that detects charge obtained by the photoelectric conversion PD by applying a predetermined voltage (first voltage) to the pixel 51, and a second charge collector that detects charge obtained by the photoelectric conversion by applying a predetermined voltage (second voltage) to the pixel 51. The first and second charge collector may include tap A and tap B, respectively. Although two charge collectors are shown (i.e., tap A, and tap B), more or fewer charge collectors may be included according to design preferences.

The tap driving unit 21 supplies the predetermined first voltage to the first charge collector of each of the pixels 51 of the pixel array unit 20 through a predetermined voltage supply line 30, and supplies the predetermined second voltage to the second charge collector thereof through the predetermined voltage supply line 30. Therefore, two voltage supply lines 30 including the voltage supply line 30 that transmits the first voltage and the voltage supply line 30 that transmits the second voltage are wired to one pixel column of the pixel array unit 20.

In the pixel array unit 20, with respect to the pixel array of the matrix shape, a pixel drive line 28 is wired along a row direction for each pixel row, and two vertical signal lines 29 are wired along a column direction for each pixel column. For example, the pixel drive line 28 transmits a drive signal for driving when reading a signal from the pixel. Note that, although FIG. 1 shows one wire for the pixel drive line 28, the pixel drive line 28 is not limited to one. One end of the pixel drive line 28 is connected to an output end corresponding to each row of the vertical driving unit 22.

The vertical driving unit 22 includes a shift register, an address decoder, or the like. The vertical driving unit 22 drives each pixel of all pixels of the pixel array unit 20 at the same time, or in row units, or the like. That is, the vertical driving unit 22 includes a driving unit that controls operation of each pixel of the pixel array unit 20, together with the system control unit 25 that controls the vertical driving unit 22.

The signals output from each pixel 51 of a pixel row in response to drive control by the vertical driving unit 22 are input to the column processing unit 23 through the vertical signal line 29. The column processing unit 23 performs a predetermined signal process on the pixel signal output from each pixel 51 through the vertical signal line 29 and temporarily holds the pixel signal after the signal process.

Specifically, the column processing unit 23 performs a noise removal process, a sample and hold (S/H) process, an analog to digital (AD) conversion process, and the like as the signal process.

The horizontal driving unit 24 includes a shift register, an address decoder, or the like, and sequentially selects unit circuits corresponding to pixel columns of the column processing unit 23. The column processing unit 23 sequentially outputs the pixel signals obtained through the signal process for each unit circuit, by a selective scan by the horizontal driving unit 24.

The system control unit 25 includes a timing generator or the like that generates various timing signals and performs drive control on the tap driving unit 21, the vertical driving unit 22, the column processing unit 23, the horizontal driving unit 24, and the like, on the basis of the various generated timing signals.

The signal processing unit 31 has at least a calculation process function and performs various signal processing such as a calculation process on the basis of the pixel signal output from the column processing unit 23. The data storage unit 32 temporarily stores data necessary for the signal processing in the signal processing unit 31. The signal processing unit 31 may control overall functions of the imaging device 1. For example, the tap driving unit 21, the vertical driving unit 22, the column processing unit 23, the horizontal driving unit 24, and the system control unit 25, and the data storage unit 32 may be under control of the signal processing unit 31. The signal processing unit or signal processor 31, alone or in conjunction with the other elements of FIG. 1, may control all operations of the systems discussed in more detail below with reference to the accompanying figures. Thus, the terms “signal processing unit” and “signal processor” may also refer to a collection of elements 21, 22, 23, 24, 25, and/or 31.

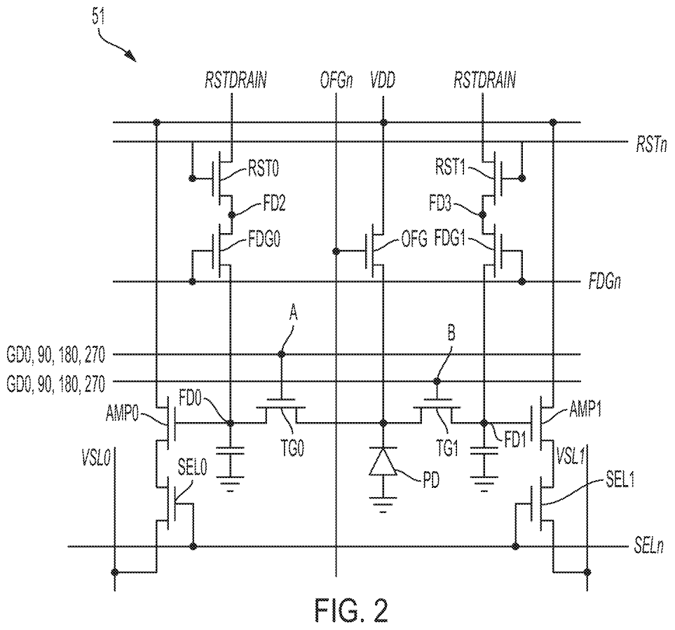

FIG. 2 illustrates an example schematic of a pixel 51 from FIG. 1. The pixel 51 includes a photoelectric conversion region PD, such as a photodiode or other light sensor, transfer transistors TG0 and TG1, floating diffusion regions FD0 and FD1, reset transistors RST0 and RST1, amplification transistors AMP0 and AMP1, and selection transistors SEL0 and SEL1. The pixel 51 may further include an overflow transistor OFG, transfer transistors FDG0 and FDG1, and floating diffusion regions FD2 and FD3.

The pixel 51 may be driven according to control signals or transfer signals GD0, GD90, GD180 and GD270 applied to gates or taps A/B of transfer transistors TG0/TG1, reset signal RSTDRAIN, overflow signal OFGn, power supply signal VDD, selection signal SELn, and vertical selection signals VSL0 and VSL1. These signals are provided by various elements from FIG. 1, for example, the tap driver 21, vertical driver 22, system controller 25, etc.

As shown in FIG. 2, the transfer transistors TG0 and TG1 are coupled to the photoelectric conversion region PD and have taps A/B that transfer charge as a result of applying transfer signals.

These transfer signals GD0, GD90, GD180, and GD270 may have different phases relative to a phase of a modulated signal from a light source (e.g., phases that differ 0 degrees, 90 degrees, 180 degrees, and/or 270 degrees). The transfer signals may be applied in a manner that allows for depth information (or pixel values) to be captured in a desired number of frames (e.g., one frame, two frames, four frames, etc.). Details regarding the application of the transfer signals to tap A and/or tap B are described in more detail below with reference to the figures.

It should be appreciated that the transfer transistors FDG0/FDG1 and floating diffusions FD2/FD3 are included to expand the charge capacity of the pixel 51, if desired. However, these elements may be omitted or not used, if desired. The overflow transistor OFG is included to transfer overflow charge from the photoelectric conversion region PD, but may be omitted or unused if desired. Further still, if only one tap is desired, then elements associated with the other tap may be unused or omitted (e.g., TG1, FD1, FDG1, RST1, SEL1, AMP1).

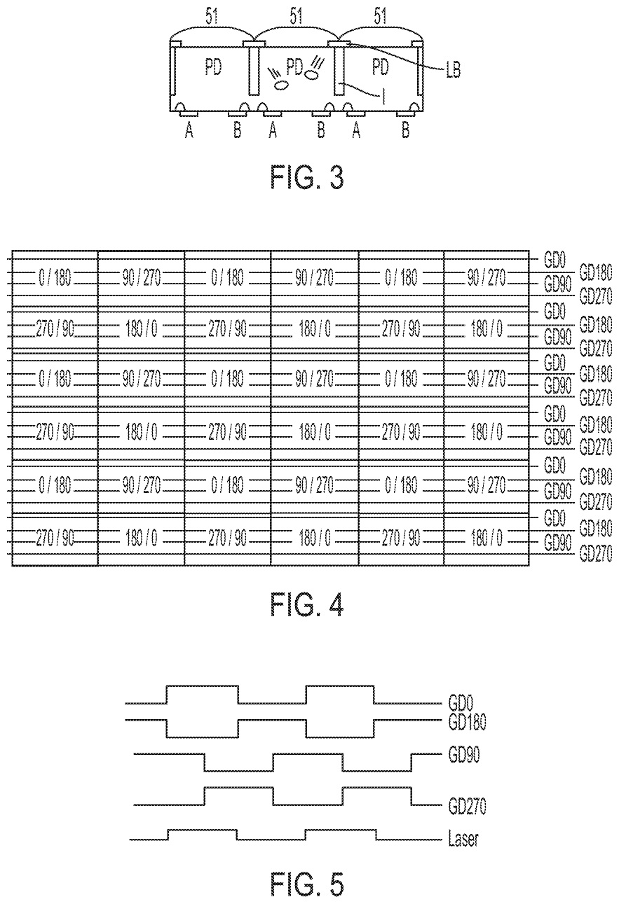

It should be understood that FIGS. 3-33 show substantially accurate relative positional relationships of the elements depicted therein and can be relied upon as support for such positional relationships. For example, the figures provide support for selection transistors SEL and amplification transistors AMP being aligned with one another in a vertical direction, while transistors FDG and RST are aligned with one another in the vertical direction. As another example, the figures provide support for a transistor on a right side of a figure being aligned with a transistor on a left side of a figure in the horizontal direction. As yet another example, the figures are generally accurate with respect to showing positions of overlapping elements.

In addition, where reference to general element or set of elements is appropriate instead of a specific element, the description may refer to the element or set of elements by its root term. For example, when reference to a specific transfer transistor TG0 or TG1 is not necessary, the description may refer to the transfer transistor(s) “TG.”

FIG. 3 illustrates a cross-sectional view of pixels in an imaging device according to at least one example embodiment. Three pixels 51 are shown, but example embodiments are not limited thereto and more or fewer pixels may be included. Each pixel 51 may include a photoelectric conversion region PD that converts incident light into electric charge, and each photoelectric conversion region may be isolated from a neighboring photoelectric conversion region by an isolation structure I that reflects and/or blocks light from entering the neighboring photoelectric conversion region. Each pixel 51 may include a light blocking structure LB for blocking light. As shown in FIGS. 1 and 2, each pixel 51 may include two taps A and B for transferring the electric charge at two different phases per pixel 51. The taps A and B may correspond to nodes at gates of transfer transistors that transfer electric charge to a remainder of a pixel circuit (e.g., to a floating diffusion FD, an amplification transistor AMP, a selection transistor SEL, an analog-to-digital converter (ADC), etc.). Although not explicitly shown, it should be understood that the gates of the transfer transistors (i.e., taps A and B) may include portions embedded into a same substrate in which the photoelectric conversion region PD is disposed.

FIG. 4 illustrates a schematic of a pixel array 20 that includes the pixels 51 of FIG. 3. In FIG. 4, each block represents one pixel 51 in the array, and the numbers within each block correspond phases of a signal applied to a signal line SL for collecting the electric charge of the respective pixel 51. Pixels 51 in FIG. 3 may correspond to the three upper left pixels in FIG. 4. As shown, the different signals applied to taps A and B are signals GD0, GD90, GD180, and GD270, having phase differences from a pulsed light source of 0 degrees, 90 degrees, 180 degrees, and 270 degrees, respectively.

FIG. 5 illustrates an example timing diagram for showing the timing of transfer signals for transferring electric charge collected at each tap A and B to, for example, a floating diffusion FD0, FD1 from FIG. 2. The timing for applying transfer signals GD0, GD90, GD180, and GD270 is illustrated in relation to the timing of a pulsed light source (e.g., a laser). For example, a transfer signal applied GD0 is in phase with the pulsed light source (i.e., shifted zero degrees), a transfer signal GD90 is shifted 90 degrees from the pulsed light source, a transfer signal GD180 is shifted 180 degrees from the pulsed light source, and a transfer signal GD270 is shifted 270 degrees from the pulsed light source.

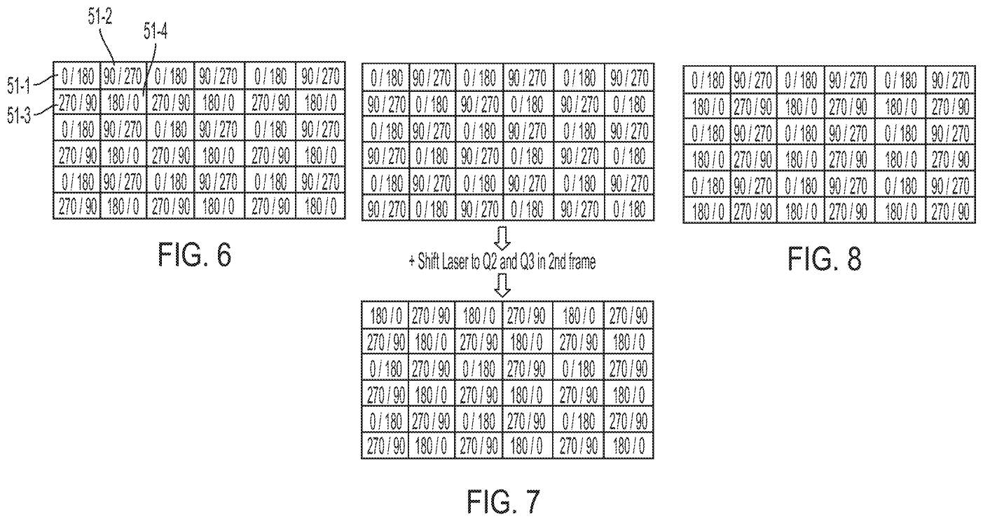

FIGS. 6-10 illustrate phase arrangements and FIGS. 11-19 illustrate layouts of pixel arrays according to example embodiments where each signal line SL that applies the transfer signals to the pixels 51 are oriented in a first direction (e.g., a vertical direction). Here, a driving circuit (e.g., tap driving unit 21) that provides the transfer signals to the signal lines SL may be provided at either end of the signal lines SL or at both ends of the signal lines SL.

FIGS. 6 and 8 illustrate example arrangements where the depth information is captured in a single frame, whereas FIGS. 7, 9, and 10 illustrate example arrangements where the depth information is captured in two frames.

With reference to FIGS. 6 and 8, charge quantities Q1, Q2, Q3, and Q4, which are desired for calculating a distance to an object, are captured in a single frame because a 2×2 grouping of pixels (e.g., upper left grouping of pixels) have taps A and B that receive all of transfer signals GD0, GD90, GD180, and GD270 in one frame. A single frame may comprise multiple modulation cycles, where a modulation cycle corresponds to a single pulse of the laser and a single application of each transfer signal GD0, GD90, GD180, and GD270 to taps A and/or B of pixels 51. For example, with reference to FIGS. 5 and 6, for one modulation cycle, the laser in FIG. 5 is pulsed once, GD0 is applied to tap A of pixel 51-1 in FIG. 6, GD180 is applied to tap B of pixel 51-1, GD90 is applied to tap A of pixel 51-2, GD270 is applied to tap B of pixel 51-2, GD270 is applied to tap A of pixel 51-3, GD90 is applied to tap B of pixel 51-3, GD180 is applied to tap A of pixel 51-4, and GD0 is applied to tap B of pixel 51-5. Applying the transfer signals GD0 to GD270 in this manner allows the desired charge quantities Q1, Q2, Q3, and Q4 to be collected by the group of four pixels 51-1 to 51-4. Upon carrying out a desired number of modulation cycles (e.g., 12 cycles), final charge quantities Q1, Q2, Q3, and Q4 are obtained and used to calculate a distance to the object. The distance is calculated according to known methods, for example, by Equation (1):

$$Distance = \frac{C \cdot Δ T}{2} = \frac{C \cdot α}{4 π {f}_{mod}} \\ α = arctan ( \frac{{ϕ}_{1} - {ϕ}_{3}}{{ϕ}_{0} - {ϕ}_{2}} ) \qquad ( 1 )$$

Here, C is the speed of light, ΔT is the time delay, fmod is the modulation frequency of the emitted light, φ0 to φ3 are the signal values Q1 to Q4 detected with transfer signals having phase differences from the emitted light 0 degrees, 90 degrees, 180 degrees, and 270 degrees, respectively.

In FIGS. 7, 9, and 10, it should be understood that the first frame of each example may transfer captured charge quantities Q1 and Q4 with signals GD0 and GD270, respectively, and the second frame of each example may transfer captured charge quantities Q2 and Q3 with signals GD90 and GD180, respectively. For the second frame in FIGS. 7, 9, and 10, the phase of the pulsed light source (e.g., a laser) may be shifted compared to the first frame, for example, by 90 degrees or 270 degrees. In this case and still with reference to FIGS. 7, 9, and 10, each second frame has a phase of the transfer signals (in relation to the light source) adjusted for the taps AB of each pixel 51 compared to the first frame. For example, in FIG. 7, the upper leftmost pixel in the first frame may receive transfer signals having phases of 0 degrees and 180 degrees at respective taps GD (e.g., 0 degrees at tap A and 180 degrees at tap B) of the pixel while in the second frame the pixel may receive transfer signals having phases of 180 degrees and 0 degrees at the respective taps (e.g., 180 degrees at tap A and 0 degrees at tap B). In at least one example embodiment, the phase of the pulsed light source in the second frame may be shifted 180 degrees from the first frame. In this case, the same transfer signals applied to the taps GD in the first frame may be applied to the taps GD in the second frame (i.e., the transfer signals applied in the second frame are not shifted compared to the first frame).

Whether phase information (i.e., charge quantities Q1 to Q4) is captured in one frame or multiple frames may be a design choice, for example, based on whether increased spatial resolution is desired or reduced motion blur is desired.

FIGS. 11-19 illustrate example layouts of the arrangements in FIGS. 6-10. For convenience of illustration, only eight pixels are shown in FIGS. 11-19, but it should be understood that the same pattern may be repeated for the entire pixel array 20. In FIGS. 11-19, each pixel 51A to 51D may include photoelectric conversion regions PD, reset transistors RST0/RST1, floating diffusions FD0/FD1, floating diffusion transistors FDG0/FDG1 (for expanding capacities of the floating diffusions FD0/FD1 if desired), selection transistors SEL0/SEL1, overflow transistors OFG0/OFG1, amplification transistors AMP0/AMP1, transfer transistors TG0/TG1 and transfer transistor taps A1, A2, A3, A4, B1, B2, B3, B4, signal lines SL0, SL90, SL180, SL270, SL0′, SL90′, SL180′, and SL270′, contacts C1, and wirings W1 to W8. Where reference to a specific element is not necessary, the description may refer to the root term of the element (e.g., a general reference to FD0/FD1 is simply FD, a general reference to taps A1, A2, A3, A4, B1, B2, B3, B4 is taps A/B, and so on). The taps A/B for each pixel 51 are arranged diagonally from one another for a respective PD. Here, it should be understood that at least some of the above elements may be formed in different planes of the imaging device. For example, the PDs and transistors, the wirings W, and the signal lines SL are formed in different planes within the imaging device (e.g., stacked on one another). Further, although octagonal PDs are shown, it should be understood that the PDs may take any desired shape according to design preferences.

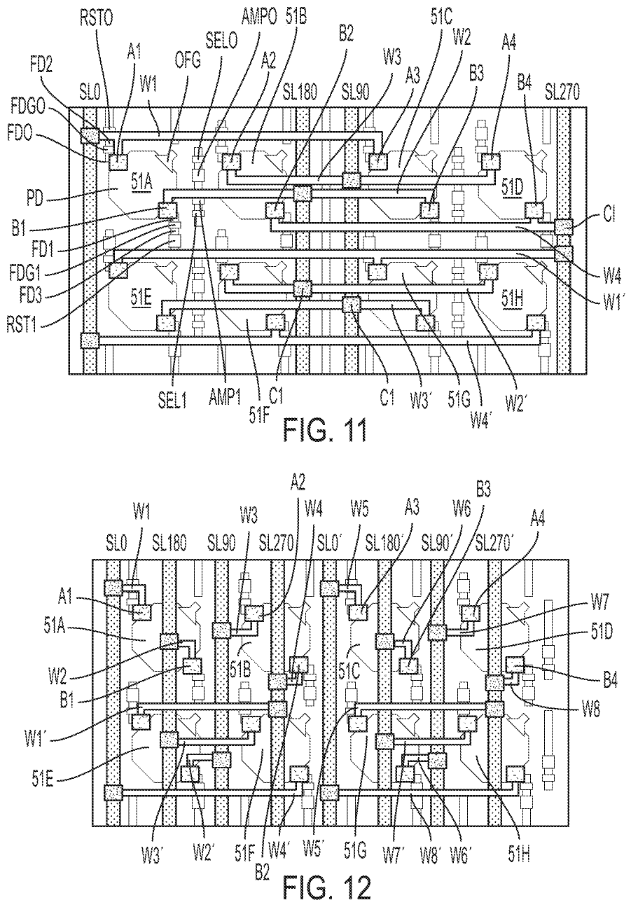

FIGS. 11 and 12 illustrate layouts for the example arrangement of FIG. 6.

FIG. 11 illustrates an example layout that includes four signal lines SL0, SL90, SL180, SL270, one signal line for each possible transfer signal at phases 0, 90, 180, and 270. Signal lines SL0 and SL270 for respective phases 0 and 270 are at outer edges of the layout while signal lines SL90 and SL180 for phases 180 and 90 are at a center of the layout. In FIG. 11 (and in other figures), the signal lines SL0 to SL270 do not overlap the PDs. However, example embodiments are not limited thereto, and one or more of the signal lines SL in FIG. 11 (and in other figures) may overlap the PDs if desired. Each signal line SL may include one or more contacts C1 (e.g., two contacts C1) that make electrical contact with a respective wiring W1, W2, W3, W4, W1′, W2′, W3′, W4′. Each wiring W1 to W4′ may be connected to one or more taps A/B that make electrical contact with a respective transfer transistor TG (e.g., a gate of the transfer transistor TG). For example, wiring W1 is connected to taps A1 and A3, wiring W2 is connected to taps A2 and A4, wiring W3 is connected to taps B1 and B3, and wiring W4 is connected to taps B2 and B4. The same connections of wirings W′ to taps A/B are true for pixels 51E to 51H. According to at least one example embodiment, the signal lines SL0 to SL270, the contacts C1, the taps A/B, and/or the wirings W1 to W4′ include aluminum. Aluminum may be the desired material for larger pixel arrays.

FIG. 11 illustrates connections to taps A and B for pixels 51A to 51H, which are repeated for all pixels in the pixel array 20. FIG. 11 also illustrates transistors and floating diffusions from the schematic of FIG. 2 for a pixel 51A. Each pixel 51B-51H and remaining pixels in the pixel array 20 have a same layout for transistors and floating diffusions as that shown for pixel 51A in FIG. 11. The layout of transistors and floating diffusions in FIGS. 10-17 and 23-28 may also be the same as that shown in FIG. 11. In the case of FIG. 11 and FIGS. 12-30, certain transistors and/or floating diffusions may be obscured by one or more signal lines SL or wirings W. Further, although not explicitly shown, additional conductors are included to make electrical connections to and/or between transistors to comply with connections shown in the schematic of FIG. 2.

FIG. 12 illustrates an example layout that includes eight signal lines SL0, SL90, SL180, SL270, SL0′, SL90′, SL180′, and SL270′ having the shown associated phases and connections to taps of pixels 51A to 51H via wirings W1 to W8′. In FIG. 12, some of the signal lines SL overlap the PDs (SL180, SL270, SL180′, and SL270′). According to at least one example embodiment, the signal lines SL0 to SL270′, the contacts C1, the taps A and B, and/or the wirings W include copper. In this case, copper or another conductor with similar conductive/resistance properties may be desired (e.g., vs. aluminum) to allow for the signal lines SL, contacts C1, taps A/B, and/or the wirings W1 to W8 to be tightly packed in a smaller pixel array. FIG. 12 illustrates a layout with a semi-global activation of the transistor transistors TG connected to a particular signal line SL. The layout is semi-global in that the current path for connecting each signal line SL to taps A and B is substantially the same for a given phase for each pixel 51, thus allowing for the transfer signals for each phase to reach the taps A and B at a same time. In other words, using the example of signal lines SL0 and SL0′, the current path to from a circuit that provides transfer signals to taps A1 and A3 through wirings W1 and W5 is substantially the same. The same is true for signal line pairs SL90/SL90′, SL180/SL180′, and SL270/SL270′.

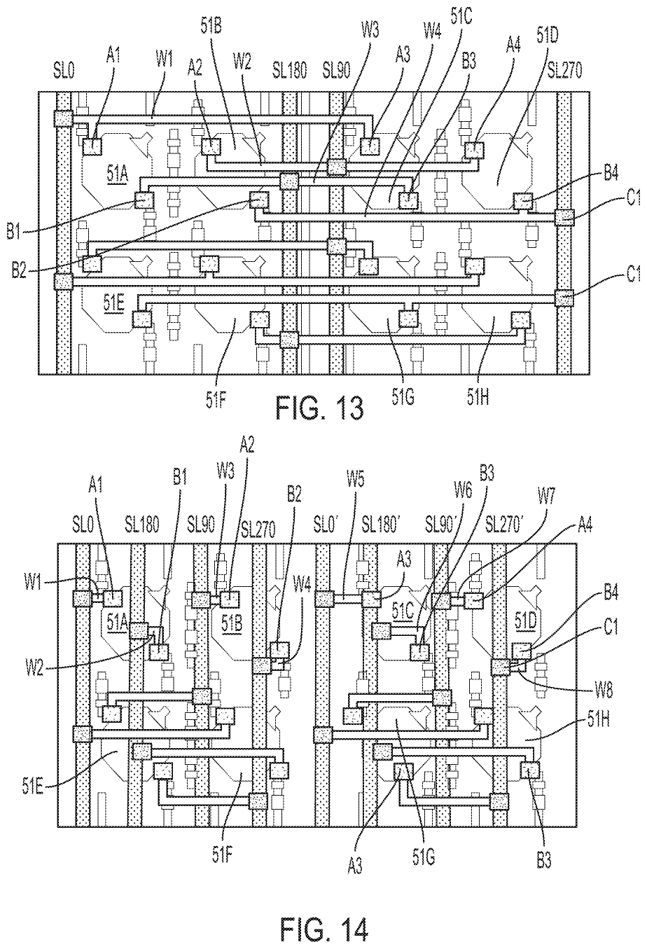

FIGS. 13 and 14 illustrate example layouts for the arrangement in FIG. 7.

FIG. 13 illustrates an example layout that includes four signal lines SL having the connections to the pixels 51A to 51H. In FIG. 13, the wirings W, contacts C1, taps A/B, and/or signal lines SL may be comprised of aluminum for the same reasons as those noted above for FIG. 11.

FIG. 14 illustrates an example layout that includes eight signal lines SL having the shown connections to the pixels 51A to 51H. In FIG. 14, the wirings W, contacts C1, taps A/B, and/or signal lines SL may be comprised of copper for the same reasons as those noted above for FIG. 12. FIG. 14 may be a layout for semi-global activation of the transfer transistors TG connected to a particular signal line SL in the same reasons as those noted above for FIG. 12.

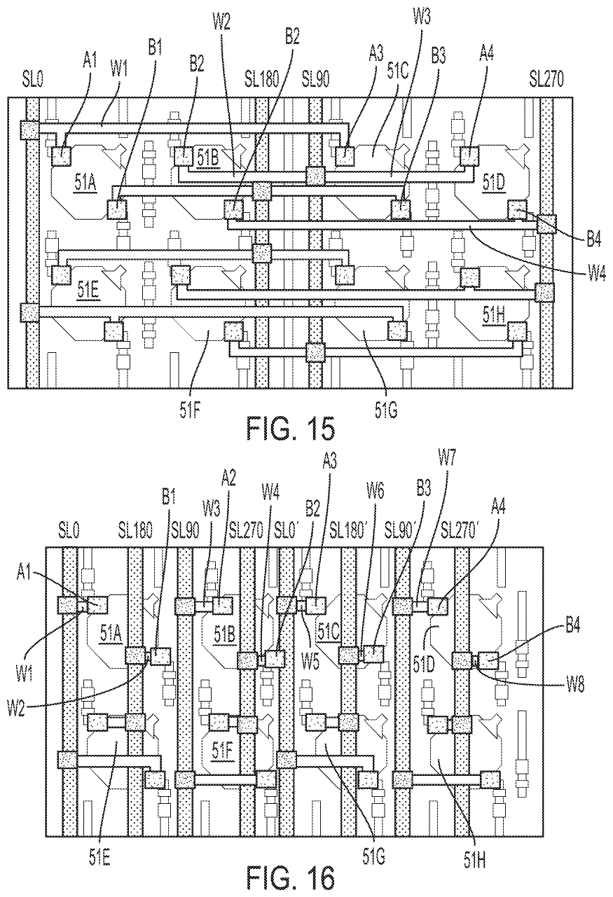

FIGS. 15 and 16 illustrate example layouts for the arrangement shown in FIG. 8.

FIG. 15 illustrates an example layout that includes four signal lines SL having the shown associated phases of transfer signals applied thereto and connections to the pixels 51A to 51H. In FIG. 15, the wirings W, contacts C1, taps A/B, and/or signal lines SL may be comprised of A1 for the same reasons as those noted above for FIG. 11.

FIG. 16 illustrates an example layout that includes eight signal lines SL having the shown associated phases of transfer signals applied thereto and connections to the pixels 51A to 51H. In FIG. 16, the wirings W, contacts C1, taps A/B, and/or signal lines SL may be comprised of copper for the same reasons as those noted above for FIG. 12. FIG. 16 may be a layout for semi-global activation of the transfer transistors TG connected to a particular signal line SL for the same reasons as those noted above for FIG. 12.

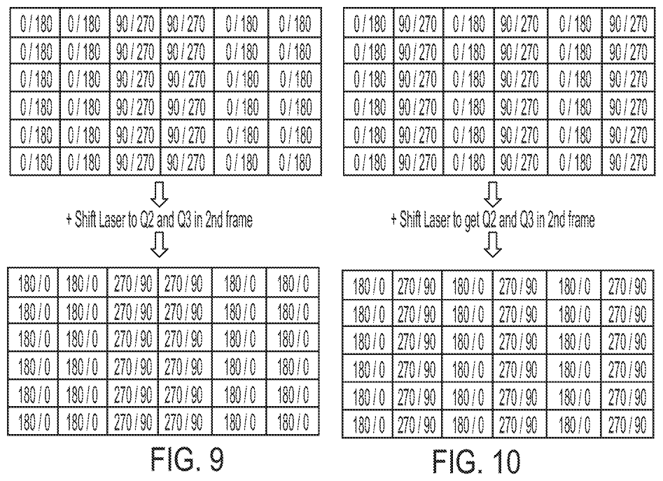

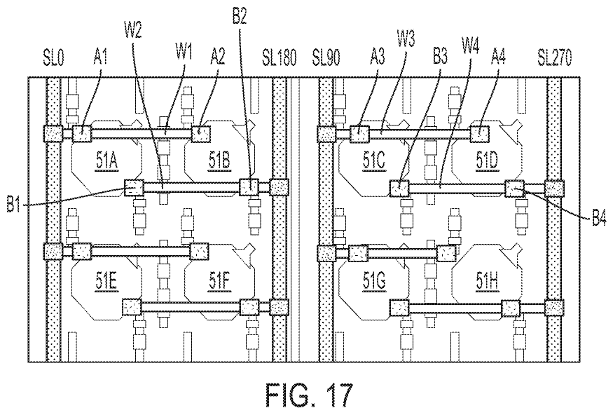

FIG. 17 illustrates an example layout for the arrangement shown in FIG. 9.

FIG. 17 illustrates an example layout that includes four signal lines SL having the shown associated phases of transfer signals applied thereto and connections to the pixels 51A to 51H. In FIG. 17, the wirings W, contacts C1, taps A/B, and/or signal lines SL may be comprised of aluminum for the same reasons as those noted above for FIG. 11.

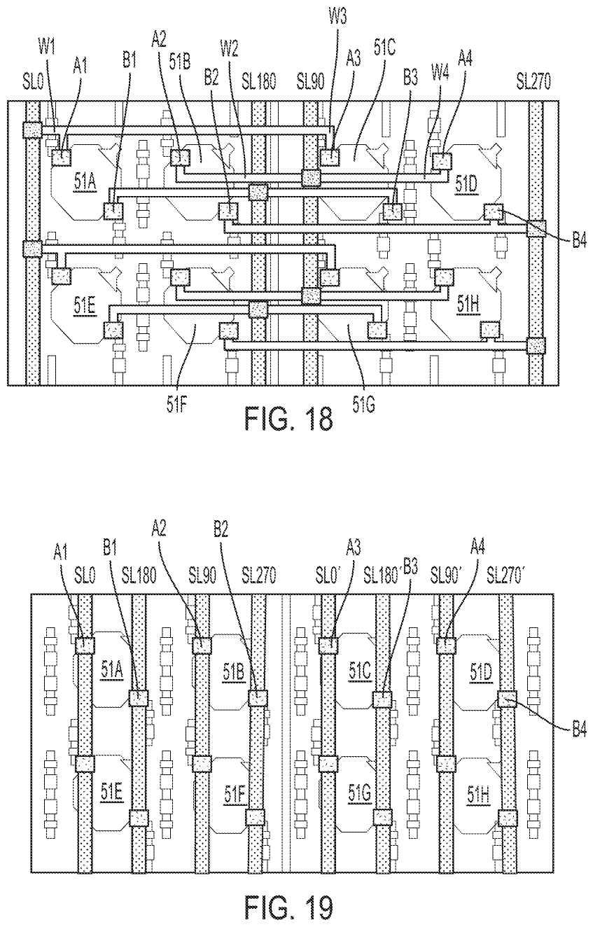

FIGS. 18 and 19 illustrate example layouts for the arrangement shown in FIG. 10.

FIG. 18 illustrates an example layout that includes four signal lines SL having the shown associated phases of transfer signals applied thereto and connections to the pixels 51A to 51H. In FIG. 18, the wirings W, contacts C1, taps A/B, and/or signal lines SL may be comprised of aluminum for the same reasons as those noted above for FIG. 11.

FIG. 19 illustrates an example layout that includes eight signal lines SL having the shown associated phases of transfer signals applied thereto and connections to the pixels 51A to 51H. In FIG. 19, the signal lines SL and/or taps A/B, may be comprised of copper for the same reasons as those noted above for FIG. 12. FIG. 19 may be a layout for semi-global activation of the transfer transistors TG connected to a particular signal line SL in the same reasons as those noted above for FIG. 12. FIG. 19 does not use contacts C1 or wirings W, thus, material costs and/or fabrication complexity may be reduced.

FIGS. 20-33 illustrate arrangements and layouts of pixel arrays according to example embodiments where each signal line SL that applies the transfer signals to the pixels 51A to 51H are oriented in a second direction (e.g., a horizontal direction). Here, a driving circuit that provides the transfer signals to the signal lines SL may be provided at either side of the signal lines or at both sides of the signal lines SL.

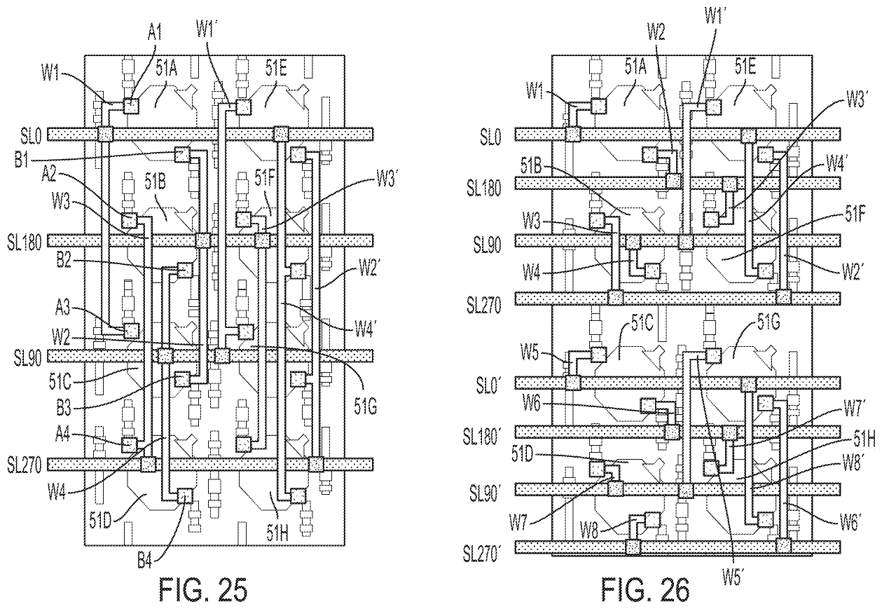

FIGS. 25-33 illustrate example layouts of the arrangements in FIGS. 20-24. For convenience of illustration, only eight pixels 51A to 51H are shown in FIGS. 25-33, but it should be understood that the same pattern may be repeated for the entire pixel array. Like FIGS. 11-19, in FIGS. 25-33, each pixel 51A to 51H may include photoelectric conversion regions PD, reset transistors RST, floating diffusions FD, selection transistors SEL, overflow transistors OFG, amplification transistors AMP, transfer transistors TG and taps A/B, signal lines SL, contacts C1, and wirings W. The transistors in FIGS. 25-33 are laid out the same or similar manner as that shown in FIGS. 11-19 while the signal lines SL in FIGS. 25-33 are arranged perpendicularly compared to the signal lines SL in FIGS. 11-19. The taps A/B for each pixel 51A to 51H are arranged diagonally from one another on a respective PD. Here, it should be understood that at least some of the above elements may be formed in different planes of the imaging device. For example, the PDs and transistors, the wirings W, and the signal lines SL are formed in different planes within the imaging device (e.g., stacked on one another). Further, although octagonal PDs are shown, it should be understood that the PDs may take any desired shape according to design preferences.

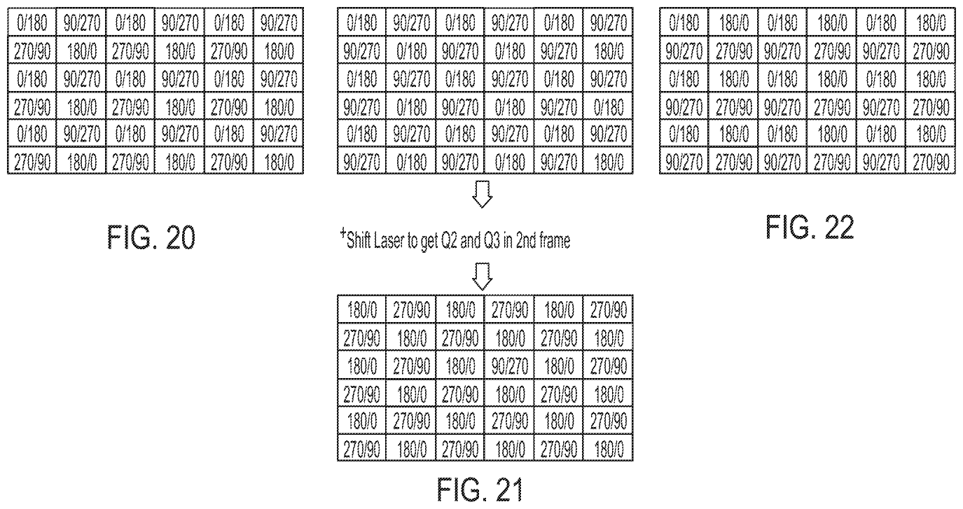

FIGS. 20 and 22 illustrate example arrangements where the depth information is captured in a single frame (like FIGS. 4 and 6), whereas FIGS. 21, 23, and 24 illustrate example arrangements where the depth information is captured in two frames (like FIGS. 7, 9, and 10). In FIGS. 21, 23, and 24, it should be understood that the first frame of each example may transfer captured charge quantities Q1 and Q4 for GD0 and GD270, respectively, and the second frame of each example may transfer captured charge quantities Q2 and Q3 for GD90 and GD180, respectively. For the second frame, the phase of the pulsed light source (e.g., a laser) may be shifted compared to the first frame, for example, by 90 degrees. In this case and still with reference to FIGS. 21, 23, and 24, each second frame has a phase of the transfer signals (in relation to the light source) adjusted for the taps A/B of each pixel 51 compared to the first frame. For example, in FIG. 21, the upper leftmost pixel 51 in the first frame may receive transfer signals having phases of 0 degrees and 180 degrees at respective taps A and B (e.g., 0 degrees at tap A and 180 degrees at tap B) of the pixel 51 while in the second frame the pixel 51 may receive transfer signals having phases of 180 degrees and 0 degrees at the respective taps A and B (e.g., 180 degrees at tap A and 0 degrees at tap B). In at least one example embodiment, the phase of the pulsed light source in the second frame may be shifted 180 degrees from the first frame. In this case, the same transfer signals applied to the taps A/B in the first frame may be applied to the taps A/B in the second frame (i.e., the transfer signals applied in the second frame are not shifted compared to the first frame).

FIGS. 25 and 26 illustrate example layouts for the arrangement shown in FIG. 20.

FIG. 25 illustrates an example layout that includes four signal lines SL having the shown associated phases of transfer signals applied thereto and connections to the pixels 51A to 51H. In FIG. 25, the wirings W, contacts C1, taps A/B, and/or signal lines SL may be comprised of aluminum for the same reasons as those noted above for FIG. 11.

FIG. 26 illustrates an example layout that includes eight signal lines SL having the shown associated phases of transfer signals applied thereto and connections to the pixels 51A to 51H. In FIG. 26, the signal lines SL, wirings W, contacts C1, and/or taps A/B, may be comprised of copper for the same reasons as those noted above for FIG. 12. FIG. 26 may be a layout for semi-global activation of the transfer transistors TG connected to a particular signal line for the same reasons as those noted above for FIG. 12.

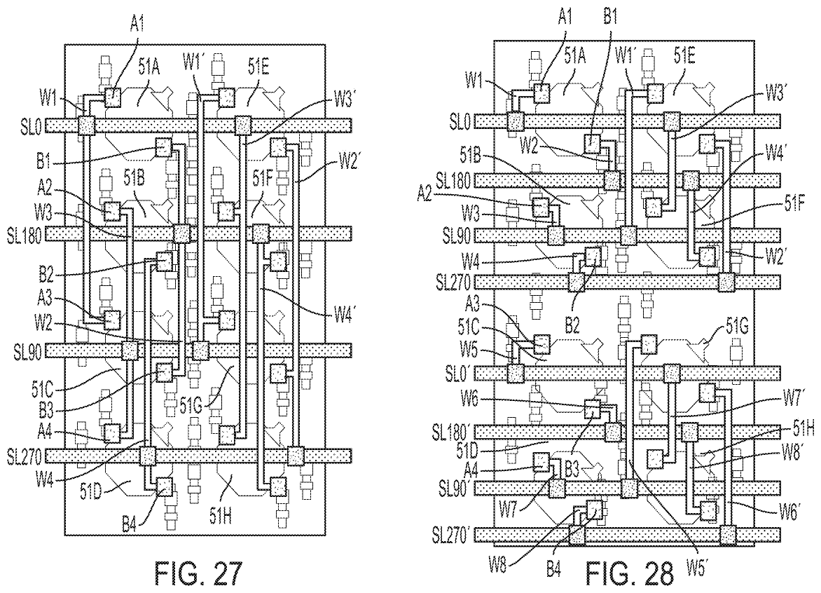

FIGS. 27 and 28 illustrate example layouts for the arrangement shown in FIG. 21.

FIG. 27 illustrates an example layout that includes four signal lines SL having the shown associated phases of transfer signals applied thereto and connections to the pixels 51A to 51H. In FIG. 27, the wirings W, contacts C1, taps A/B, and/or signal lines SL may be comprised of aluminum for the same reasons as those noted above for FIG. 11.

FIG. 28 illustrates an example layout that includes eight signal lines SL having the shown associated phases of transfer signals applied thereto and connections to the pixels 51A to 51H. In FIG. 28, the signal lines SL, wirings W, contacts C1, and/or taps A/B, may be comprised of copper for the same reasons as those noted above for FIG. 12. FIG. 28 may be a layout for semi-global activation of the transfer transistors TG connected to a particular signal line in the same reasons as those noted above for FIG. 12.

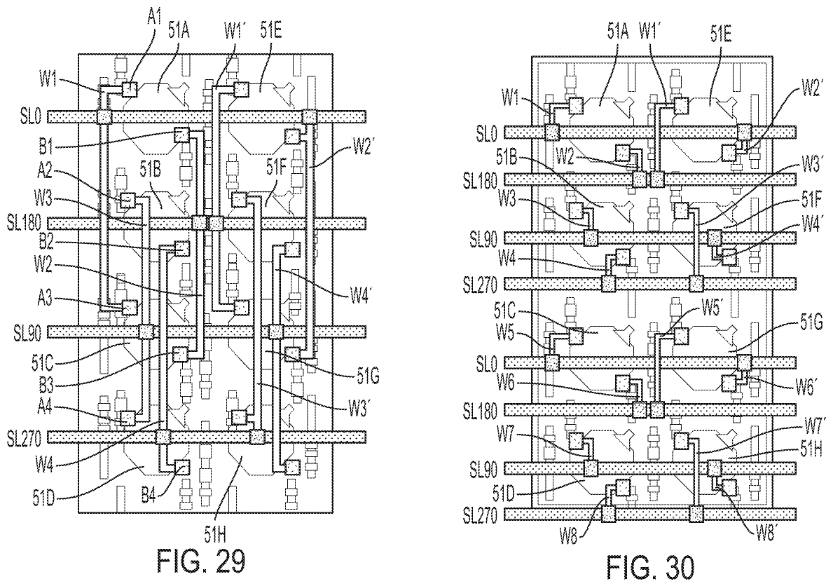

FIGS. 29 and 30 illustrate example layouts for the arrangement shown in FIG. 22.

FIG. 29 illustrates an example layout that includes four signal lines SL having the shown associated phases of transfer signals applied thereto and connections to the pixels 51A to 51H. In FIG. 29, the wirings W, contacts C1, taps A/B, and/or signal lines SL may be comprised of aluminum for the same reasons as those noted above for FIG. 11.

FIG. 30 illustrates an example layout that includes eight signal lines SL having the shown associated phases of transfer signals applied thereto and connections to the pixels 51A to 51H. In FIG. 30, the signal lines SL, wirings W, contacts C1, and/or taps A/B, may be comprised of copper for the same reasons as those noted above for FIG. 12. FIG. 30 may be a layout for semi-global activation of the transfer transistors TG connected to a particular signal line in the same reasons as those noted above for FIG. 12.

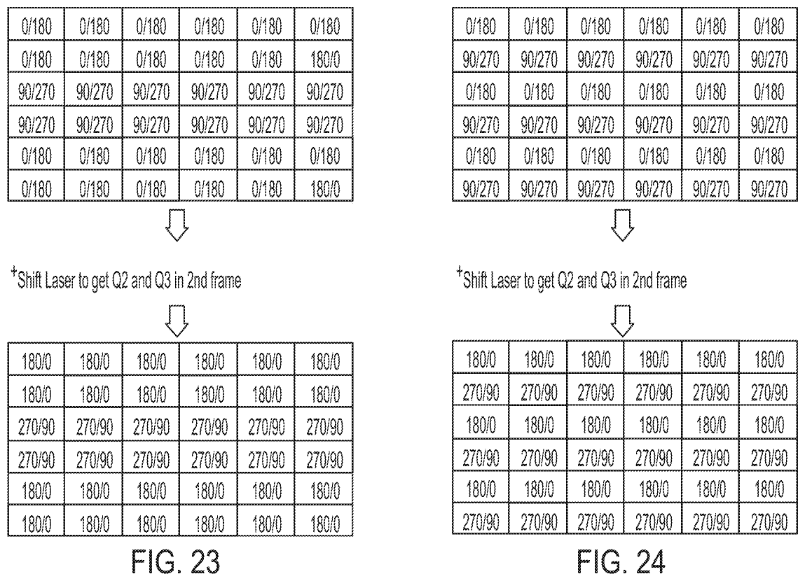

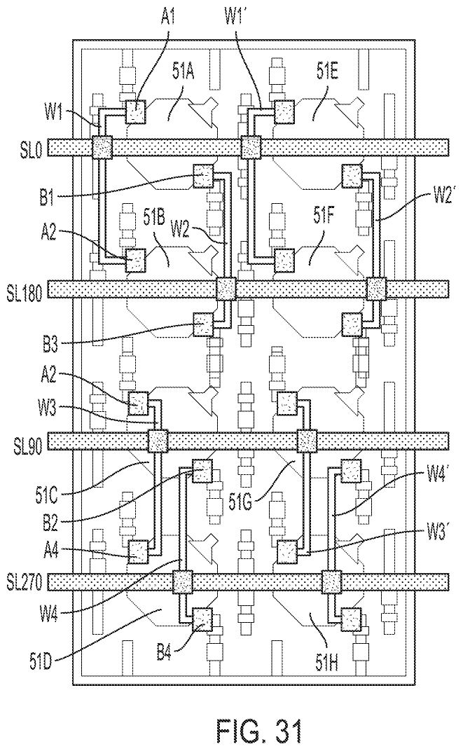

FIG. 31 illustrates an example layout for the arrangement shown in FIG. 23.

FIG. 31 illustrates an example layout that includes four signal lines SL having the shown associated phases of transfer signals applied thereto and connections to pixels 51A to 51H. In FIG. 31, the wirings W, contacts C1, taps A/B, and/or signal lines SL may be comprised of aluminum for the same reasons as those noted above for FIG. 11.

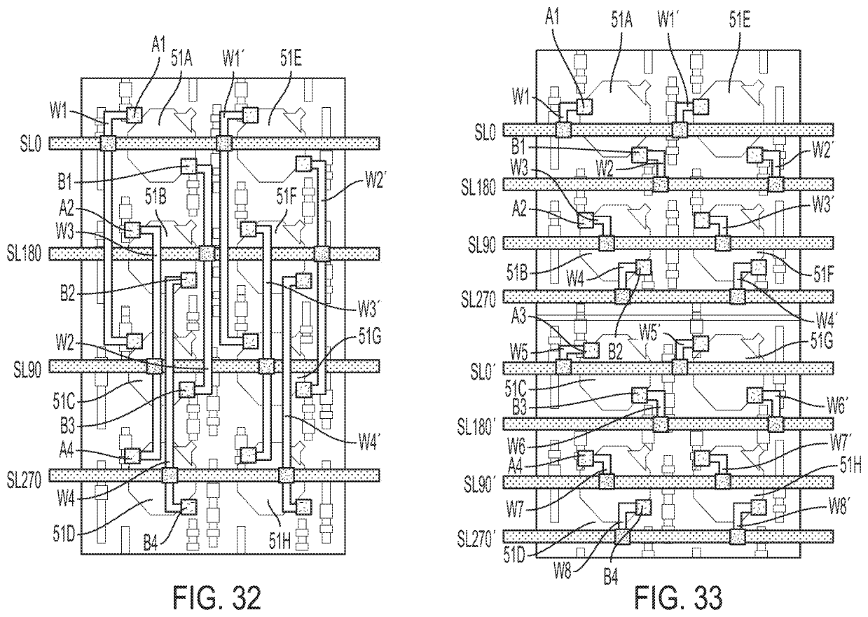

FIGS. 32 and 33 illustrate example layouts for the arrangement shown in FIG. 24.

FIG. 32 illustrates an example layout that includes four signal lines SL having the shown associated phases of transfer signals applied thereto and connections to pixels 51A to 51H. In FIG. 30, the wirings W, contacts C1, taps A/B, and/or signal lines SL may be comprised of aluminum for the same reasons as those noted above for FIG. 11.

FIG. 33 illustrates an example layout that includes eight signal lines SL having the shown associated phases of transfer signals applied thereto and connections to the pixels 51A to 51H. In FIG. 33, the signal lines SL, wirings W, contacts C1, and/or taps A/B, may be comprised of copper for the same reasons as those noted above for FIG. 12. FIG. 33 may be a layout for semi-global activation of the transfer transistors TG connected to a particular signal line SL for the same reasons as those noted above for FIG. 12.

Systems/devices that may incorporate the above described imaging device will now be described.

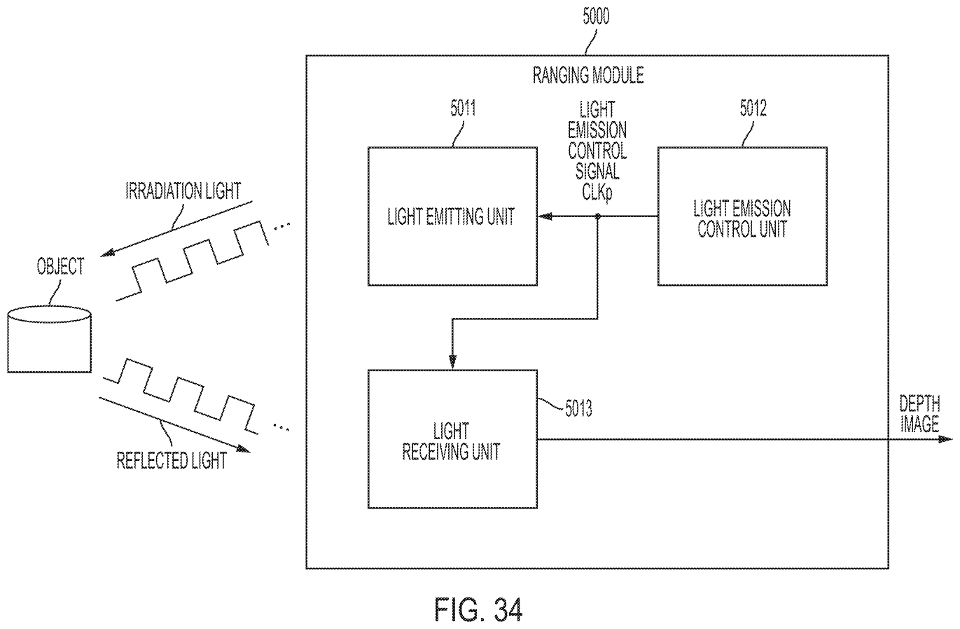

FIG. 34 is a block diagram illustrating an example of a ranging module according to at least one example embodiment.

The ranging module 5000 includes a light emitting unit 5011, a light emission control unit 5012, and a light receiving unit 5013.

The light emitting unit 5011 has a light source that emits light having a predetermined wavelength, and irradiates the object with irradiation light of which brightness periodically changes. For example, the light emitting unit 5011 has a light emitting diode that emits infrared light having a wavelength in a range of 780 nm to 1000 nm as a light source, and generates the irradiation light in synchronization with a light emission control signal CLKp of a rectangular wave supplied from the light emission control unit 5012.

Note that, the light emission control signal CLKp is not limited to the rectangular wave as long as the control signal CLKp is a periodic signal. For example, the light emission control signal CLKp may be a sine wave.

The light emission control unit 5012 supplies the light emission control signal CLKp to the light emitting unit 5011 and the light receiving unit 5013 and controls an irradiation timing of the irradiation light. A frequency of the light emission control signal CLKp is, for example, 20 megahertz (MHz). Note that, the frequency of the light emission control signal CLKp is not limited to 20 megahertz (MHz), and may be 5 megahertz (MHz) or the like.

The light receiving unit 5013 receives reflected light reflected from the object, calculates the distance information for each pixel according to a light reception result, generates a depth image in which the distance to the object is represented by a gradation value for each pixel, and outputs the depth image.

The above-described imaging device 1 is used for the light receiving unit 5013, and for example, the imaging device 1 serving as the light receiving unit 5013 calculates the distance information for each pixel from a signal intensity detected by each tap A/B, on the basis of the light emission control signal CLKp.

As described above, the imaging device 1 shown in FIG. 1 is able to be incorporated as the light receiving unit 5013 of the ranging module 5000 that obtains and outputs the information associated with the distance to the subject by the indirect ToF method. By adopting the imaging device 1 of one or more of the embodiments described above, it is possible to improve one or more distance measurement characteristics of the ranging module 5000 (e.g., distance accuracy, speed of measurement, and/or the like).

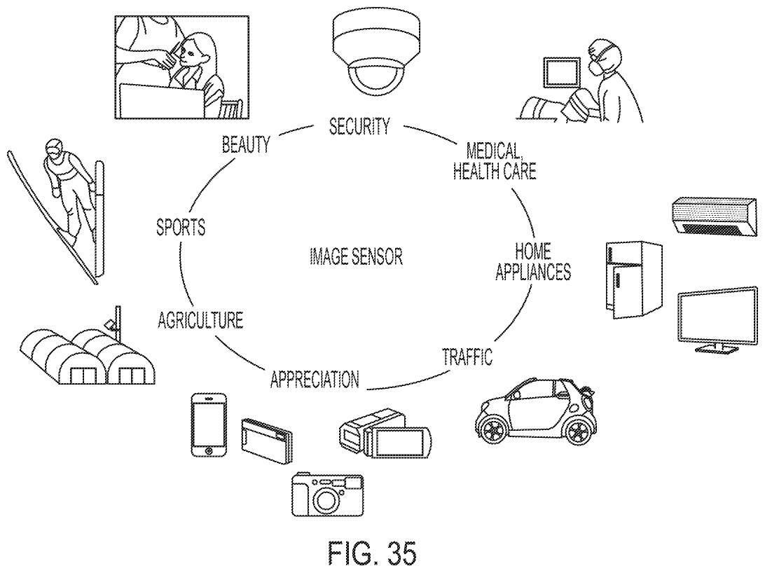

FIG. 35 is a diagram illustrating use examples of an imaging device 1 according to at least one example embodiment.

For example, the above-described imaging device 1 (image sensor) can be used in various cases of sensing light such as visible light, infrared light, ultraviolet light, and X-rays as described below. The imaging device 1 may be included in apparatuses such as a digital still camera and a portable device with a camera function which capture images, apparatuses for traffic such as an in-vehicle sensor that captures images of a vehicle to enable automatic stopping, recognition of a driver state, measuring distance, and the like. The imaging device 1 may be included in apparatuses for home appliances such as a TV, a refrigerator, and an air-conditioner in order to photograph a gesture of a user and to perform an apparatus operation in accordance with the gesture. The imaging device 1 may be included in apparatuses for medical or health care such as an endoscope and an apparatus that performs angiography through reception of infrared light. The imaging device 1 may be included in apparatuses for security such as a security monitoring camera and a personal authentication camera. The imaging device 1 may be included in an apparatus for beauty such as a skin measuring device that photographs skin. The imaging device 1 may be included in apparatuses for sports such as an action camera, a wearable camera for sports, and the like. The imaging device 1 may be included in apparatuses for agriculture such as a camera for monitoring a state of a farm or crop.

With reference to FIGS. 1-35, at least one example embodiment is directed to an imaging device 1 including a first pixel 51A. The first pixel 51A includes a first photoelectric conversion region PD, a first transfer transistor TG0 coupled to the first photoelectric conversion region PD, and a second transfer transistor TG1 coupled to the first photoelectric conversion region PD. The imaging device 1 includes a second pixel 51B adjacent to the first pixel 51A in a first direction (e.g., horizontal direction or vertical direction) and includes a second photoelectric conversion region PD, a third transfer transistor TG0 coupled to the second photoelectric conversion region PD, a fourth transfer transistor TG1 coupled to the second photoelectric conversion region PD. The imaging device 1 includes a first signal line SL0 coupled to the first transfer transistor TG0 (through tap A1) and that receives a first transfer signal having a first phase in relation to a phase of a driving signal driving a light source. The first phase may be 0 degrees. The imaging device 1 includes a second signal line SL180 coupled to the second transfer transistor TG1 (through tap B1) and that receives a second transfer signal having a second phase in relation to the phase of the driving signal. The second phase may be 180 degrees. The imaging device 1 includes a third signal line SL90 coupled to the third transfer transistor TG0 (through tap A2) and that receives a third transfer signal having a third phase in relation to the phase of the driving signal. The third phase may be 90 degrees. The imaging device 1 includes a fourth signal line SL270 coupled to the fourth transfer transistor TG1 through tap B2 and that receives a fourth transfer signal having a fourth phase in relation to the phase of the driving signal. The fourth phase may be 270 degrees so that the first, second, third, and fourth phases are different from one another.

The imaging device 1 includes a third pixel 51C adjacent to the second pixel 51B in the first direction. The third pixel 51C includes a third photoelectric conversion region PD, a fifth transfer transistor TG0 coupled to the third photoelectric conversion region PD, and a sixth transfer transistor TG1 coupled to the third photoelectric conversion region PD. The imaging device 1 includes a fourth pixel 51D adjacent to the third pixel 51C in the first direction. The fourth pixel 51D includes a fourth photoelectric conversion region PD, a seventh transfer transistor TG0 coupled to the fourth photoelectric conversion region PD, and an eighth transfer transistor TG1 coupled to the fourth photoelectric conversion region PD. According to at least one example embodiment, the fifth transfer transistor is coupled to the first signal line SL0, the sixth transfer transistor is coupled to the second signal line SL180, the seventh transfer transistor is coupled to the third signal line SL90, and the eighth transfer transistor is coupled to the fourth signal line SL270.

The imaging device 1 includes a first wiring W1 that couples the first and fifth transfer transistors to the first signal line SL0, a second wiring W2 that couples the second and sixth transfer transistors to the second signal line SL180, a third wiring W3 that couples the third and seventh transfer transistors to the third signal line SL90, and a fourth wiring W4 that couples the fourth and eighth transfer transistors to the fourth signal line SL270.

According to at least one example embodiment, the first, second, third, and fourth signal lines SL0, SL180, SL90, and SL270 extend in a second direction perpendicular to the first direction. For example, if the first direction is the horizontal direction, then the second direction is the vertical direction, and if the first direction is the vertical direction, then the second direction is the horizontal direction.

As illustrated in the figures, the first, second, third, and fourth wirings W1 to W4 extend in the first direction. For example, portions of one or more wirings W1 to W4 may extend horizontally while other portions of one or more wirings W1 to W4 may extend vertically.

As also illustrated in the figures, in a plan view, each of the first, second, third, and fourth wirings W1 to W4 overlaps at least one of the first, second, third, and fourth signal lines SL0 to SL270. As further shown, in a plan view, the second and third signal lines SL180 and SL90 are between the first and fourth signal lines SL0 and SL270. In one or more example embodiments, in the plan view, the second and third signal lines SL180 and SL90 are between the second photoelectric conversion region PD of pixel 51B and the third photoelectric conversion region PD of pixel 51C. In at least one example embodiment, in the plan view, the first signal line SL0 overlaps the first photoelectric conversion region PD of the first pixel 51A, the second signal line SL180 overlaps the second photoelectric conversion region PD of the second pixel 51B, the third signal line SL90 overlaps the third photoelectric conversion region PD of the third pixel 51C, and the fourth signal line SL270 overlaps the fourth photoelectric conversion region PD of the fourth pixel 51D (see, e.g., FIG. 22).

According to at least one example embodiment, the imaging device 1 includes a fifth signal line SL0′ coupled to the fifth transfer transistor of the third pixel 51C and that receives the first transfer signal. A sixth signal line SL180′ is coupled to the sixth transfer transistor of the third pixel 51C and receives the second transfer signal. A seventh signal line SL90′ is coupled to the seventh transfer transistor of the fourth pixel 51D and receives the third transfer signal. An eighth signal line SL270′ is coupled to the eighth transfer transistor and receives the fourth transfer signal.

As shown in FIG. 12, for example, the imaging device 1 may include a first wiring W1 that couples the first transfer transistor to the first signal line SL0, a second wiring W2 that couples the second transfer transistor to the second signal line SL180, a third wiring W3 that couples the third transfer transistor to the third signal line SL90, and a fourth wiring W4 that couples the fourth transfer transistor to the fourth signal line SL270. FIG. 12 (and other figures) further show a fifth wiring W5 that couples the fifth transfer transistor to the fifth signal line SL0′, a sixth wiring W6 that couples the sixth transfer transistor to the sixth signal line SL180′, a seventh wiring W7 that couples the seventh transfer transistor to the seventh signal line SL90′, and an eighth wiring W8 that couples the eighth transfer transistor to the eighth signal line SL270′.

In at least one example embodiment, lengths of the first wiring W1 and the fifth wiring W5 are the same, lengths of the second wiring W2 and the sixth wiring W6 are the same, lengths of the third wiring W3 and the seventh wiring W7 are the same, and lengths of the fourth wiring W4 and the eighth wiring W8 are the same. Wirings having these length relationships allow for substantially global activation of transfer transistors connect to wirings that receive a same phase transfer signal.

As shown in the figures, the first, second, third, fourth, fifth, sixth, seventh, and eighth signal lines SL0 to SL270′ extend in a second direction perpendicular to the first direction. For example, in FIG. 12, the signal lines SL0 to SL270′ extend in a vertical direction while pixels 51A to 51D are adjacent to one another in a horizontal direction. On the other hand, in FIG. 26, pixels 51A to 51D are adjacent to one another in a vertical direction while the signal lines SL0 to SL270′ extend in a horizontal direction. In a plan view as in FIG. 26, the second signal line SL180 is between the first photoelectric conversion region PD of the first pixel 51A and the second photoelectric conversion region PD of the second pixel 51B, the fourth signal line SL270 is between the second photoelectric conversion region PD of the second pixel 51B and third photoelectric conversion region PD of the third pixel 51C, the sixth signal line SL180′ is between the third photoelectric conversion region PD of the third pixel 51C and the fourth photoelectric conversion region PD of the fourth pixel 51D. As further shown in FIG. 26, for example, in the plan view, the first signal line SL0 overlaps the first photoelectric conversion region PD of the first pixel 51A, the third signal line SL90 overlaps the second photoelectric conversion region PD of the second pixel 51B, the fifth signal line SL0′ overlaps the third photoelectric conversion region PD of the pixel 51C, and the seventh signal line SL90′ overlaps the fourth photoelectric conversion region PD of the fourth pixel 51D.

At least one example embodiment is directed to a system including a light source 5011 configured to emit a light signal according to a driving signal, and an imaging device 1 as described above.

At least one example embodiment is directed to a system including a driver 5012 that emits a driving signal that includes the light source 5011 and the imaging device 1 described above.

Here, it should be appreciated that the foregoing description regarding relative lengths of wirings W, the overlapping nature of certain elements, relative directions of elements, and other aspects of example embodiments apply to one or more figures other than those specifically mentioned above, as would be understood by one skilled in the art.

Any processing devices, control units, processing units, etc. discussed above may correspond to one or many computer processing devices, such as a Field Programmable Gate Array (FPGA), an Application-Specific Integrated Circuit (ASIC), any other type of Integrated Circuit (IC) chip, a collection of IC chips, a microcontroller, a collection of microcontrollers, a microprocessor, Central Processing Unit (CPU), a digital signal processor (DSP) or plurality of microprocessors that are configured to execute the instructions sets stored in memory.

As will be appreciated by one skilled in the art, aspects of the present disclosure may be illustrated and described herein in any of a number of patentable classes or context including any new and useful process, machine, manufacture, or composition of matter, or any new and useful improvement thereof. Accordingly, aspects of the present disclosure may be implemented entirely hardware, entirely software (including firmware, resident software, micro-code, etc.) or combining software and hardware implementation that may all generally be referred to herein as a “circuit,” “module,” “component,” or “system.” Furthermore, aspects of the present disclosure may take the form of a computer program product embodied in one or more computer readable media having computer readable program code embodied thereon.

Any combination of one or more computer readable media may be utilized. The computer readable media may be a computer readable signal medium or a computer readable storage medium. A computer readable storage medium may be, for example, but not limited to, an electronic, magnetic, optical, electromagnetic, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), an appropriate optical fiber with a repeater, a portable compact disc read-only memory (CD-ROM), an optical storage device, a magnetic storage device, or any suitable combination of the foregoing. In the context of this document, a computer readable storage medium may be any tangible medium that can contain or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable signal medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Scala, Smalltalk, Eiffel, JADE, Emerald, C++, C#, VB.NET, Python or the like, conventional procedural programming languages, such as the “C” programming language, Visual Basic, Fortran 2003, Perl, COBOL 2002, PHP, ABAP, dynamic programming languages such as Python, Ruby and Groovy, or other programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider) or in a cloud computing environment or offered as a service such as a Software as a Service (SaaS).

Aspects of the present disclosure are described herein with reference to flowchart illustrations and/or block diagrams of methods, apparatuses (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable instruction execution apparatus, create a mechanism for implementing the functions/acts specified in the flowchart and/or block diagram block or blocks.

These computer program instructions may also be stored in a computer readable medium that when executed can direct a computer, other programmable data processing apparatus, or other devices to function in a particular manner, such that the instructions when stored in the computer readable medium produce an article of manufacture including instructions which when executed, cause a computer to implement the function/act specified in the flowchart and/or block diagram block or blocks. The computer program instructions may also be loaded onto a computer, other programmable instruction execution apparatus, or other devices to cause a series of operational steps to be performed on the computer, other programmable apparatuses or other devices to produce a computer implemented process such that the instructions which execute on the computer or other programmable apparatus provide processes for implementing the functions/acts specified in the flowchart and/or block diagram block or blocks.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as an embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

Inventive concepts may be configured as follows:

(1) An imaging device, comprising:

a first pixel including:
a first photoelectric conversion region;
a first transfer transistor coupled to the first photoelectric conversion region; and
a second transfer transistor coupled to the first photoelectric conversion region;

a second pixel adjacent to the first pixel in a first direction and including:
a second photoelectric conversion region;
a third transfer transistor coupled to the second photoelectric conversion region; and
a fourth transfer transistor coupled to the second photoelectric conversion region;

a first signal line coupled to the first transfer transistor and that receives a first transfer signal having a first phase in relation to a phase of a driving signal driving a light source;

a second signal line coupled to the second transfer transistor and that receives a second transfer signal having a second phase in relation to the phase of the driving signal;

a third signal line coupled to the third transfer transistor and that receives a third transfer signal having a third phase in relation to the phase of the driving signal; and

a fourth signal line coupled to the fourth transfer transistor and that receives a fourth transfer signal having a fourth phase in relation to the phase of the driving signal, wherein the first, second, third, and fourth phases are different from one another.

(2) The imaging device of (1), further comprising:

a third pixel adjacent to the second pixel in the first direction and including:
a third photoelectric conversion region;
a fifth transfer transistor coupled to the third photoelectric conversion region; and
a sixth transfer transistor coupled to the third photoelectric conversion region; and

a fourth pixel adjacent to the third pixel in the first direction and including:
a fourth photoelectric conversion region;
a seventh transfer transistor coupled to the fourth photoelectric conversion region; and
an eighth transfer transistor coupled to the fourth photoelectric conversion region.

(3) The imaging device of one or more of (1) to (2), wherein the fifth transfer transistor is coupled to the first signal line, the sixth transfer transistor is coupled to the second signal line, the seventh transfer transistor is coupled to the third signal line, and the eighth transfer transistor is coupled to the fourth signal line.

(4) The imaging device of one or more of (1) to (3), further comprising:

a first wiring that couples the first and fifth transfer transistors to the first signal line;

a second wiring that couples the second and sixth transfer transistors to the second signal line;

a third wiring that couples the third and seventh transfer transistors to the third signal line; and

a fourth wiring that couples the fourth and eighth transfer transistors to the fourth signal line.

(5) The imaging device of one or more of (1) to (4), wherein the first, second, third, and fourth signal lines extend in a second direction perpendicular to the first direction.

(6) The imaging device of one or more of (1) to (5), wherein the first, second, third, and fourth wirings extend in the first direction.

(7) The imaging device of one or more of (1) to (6), wherein, in a plan view, each of the first, second, third, and fourth wirings overlaps at least one of the first, second, third, and fourth signal lines.

(8) The imaging device of one or more of (1) to (7), wherein, in a plan view, the second and third signal lines are between the first and fourth signal lines.

(9) The imaging device of one or more of (1) to (8), wherein, in the plan view, the second and third signal lines are between the second photoelectric conversion region and the third photoelectric conversion region.

(10) The imaging device of one or more of (1) to (9), wherein, in the plan view, the first signal line overlaps the first photoelectric conversion region, the second signal line overlaps the second photoelectric conversion region, the third signal line overlaps the third photoelectric conversion region, and the fourth signal line overlaps the fourth photoelectric conversion region.

(11) The imaging device of one or more of (1) to (10), further comprising:

a fifth signal line coupled to the fifth transfer transistor and that receives the first transfer signal;

a sixth signal line coupled to the sixth transfer transistor and that receives the second transfer signal;

a seventh signal line coupled to the seventh transfer transistor and that receives the third transfer signal; and

an eighth signal line coupled to the eighth transfer transistor and that receives the fourth transfer signal.

(12) The imaging device of one or more of (1) to (11), further comprising:

a first wiring that couples the first transfer transistor to the first signal line;

a second wiring that couples the second transfer transistor to the second signal line;

a third wiring that couples the third transfer transistor to the third signal line; and

a fourth wiring that couples the fourth transfer transistor to the fourth signal line;

a fifth wiring that couples the fifth transfer transistor to the fifth signal line;

a sixth wiring that couples the sixth transfer transistor to the sixth signal line;

a seventh wiring that couples the seventh transfer transistor to the seventh signal line; and

an eighth wiring that couples the eighth transfer transistor to the eighth signal line.

(13) The imaging device of one or more of (1) to (12), wherein lengths of the first wiring and the fifth wiring are the same, lengths of the second wiring and the sixth wiring are the same, lengths of the third wiring and the seventh wiring are the same, and lengths of the fourth wiring and the eighth wiring are the same.

(14) The imaging device of one or more of (1) to (13), wherein the first, second, third, fourth, fifth, sixth, seventh, and eighth signal lines extend in a second direction perpendicular to the first direction.

(15) The imaging device of one or more of (1) to (14), wherein, in a plan view, the second signal line is between the first photoelectric conversion region and the second photoelectric conversion region, the fourth signal line is between the second photoelectric conversion region and third photoelectric conversion region, the sixth signal line is between the third photoelectric conversion region and the fourth photoelectric conversion region.

(16) The imaging device of one or more of (1) to (15), wherein, in the plan view, the first signal line overlaps the first photoelectric conversion region, the third signal line overlaps the second photoelectric conversion region, the fifth signal line overlaps the third photoelectric conversion region, and the seventh signal line overlaps the fourth photoelectric conversion region.

(17) A system, comprising:

a light source configured to emit a light signal according to a driving signal; and an imaging device including:

a first pixel including:
a first photoelectric conversion region;
a first transfer transistor coupled to the first photoelectric conversion region; and
a second transfer transistor coupled to the first photoelectric conversion region;

a second pixel adjacent to the first pixel in a first direction and including:
a second photoelectric conversion region;
a third transfer transistor coupled to the second photoelectric conversion region; and
a fourth transfer transistor coupled to the second photoelectric conversion region;

a first signal line coupled to the first transfer transistor and that receives a first transfer signal having a first phase in relation to a phase of the driving signal;

a second signal line coupled to the second transfer transistor and that receives a second transfer signal having a second phase in relation to the phase of the driving signal;

a third signal line coupled to the third transfer transistor and that receives a third transfer signal having a third phase in relation to the phase of the driving signal; and

a fourth signal line coupled to the fourth transfer transistor and that receives a fourth transfer signal having a fourth phase in relation to the phase of the driving signal, wherein the first, second, third, and fourth phases are different from one another.

(18) The system of (17), wherein the imaging device further comprises:

a third pixel adjacent to the second pixel in the first direction and including:
a third photoelectric conversion region;
a fifth transfer transistor coupled to the third photoelectric conversion region; and
a sixth transfer transistor coupled to the third photoelectric conversion region; and

a fourth pixel adjacent to the third pixel in the first direction and including:
a fourth photoelectric conversion region;
a seventh transfer transistor coupled to the fourth photoelectric conversion region; and
an eighth transfer transistor coupled to the fourth photoelectric conversion region, wherein the fifth transfer transistor is coupled to the first signal line, the sixth transfer transistor is coupled to the second signal line, the seventh transfer transistor is coupled to the third signal line, and the eighth transfer transistor is coupled to the fourth signal line.

(19) The system of one or more of (17) to (18), wherein the imaging device further comprises:

a third pixel adjacent to the second pixel in the first direction and including:
a third photoelectric conversion region;
a fifth transfer transistor coupled to the third photoelectric conversion region; and
a sixth transfer transistor coupled to the third photoelectric conversion region; and

a fourth pixel adjacent to the third pixel in the first direction and including:
a fourth photoelectric conversion region;
a seventh transfer transistor coupled to the fourth photoelectric conversion region;

a fifth signal line coupled to the fifth transfer transistor and that receives the first transfer signal;

a sixth signal line coupled to the sixth transfer transistor and that receives the second transfer signal;

a seventh signal line coupled to the seventh transfer transistor and that receives the third transfer signal; and

an eighth signal line coupled to the eighth transfer transistor and that receives the fourth transfer signal.

(20) A system, comprising:

a driver that emits a driving signal;

a light source configured to emit light according to the driving signal; and

an imaging device including:
a first pixel including:
   a first photoelectric conversion region;
   a first transfer transistor coupled to the first photoelectric conversion region; and
   a second transfer transistor coupled to the first photoelectric conversion region;
a second pixel adjacent to the first pixel in a first direction and including:
   a second photoelectric conversion region;
   a third transfer transistor coupled to the second photoelectric conversion region; and
   a fourth transfer transistor coupled to the second photoelectric conversion region;
a first signal line coupled to the first transfer transistor and that receives a first transfer signal having a first phase in relation to a phase of the driving signal;
a second signal line coupled to the second transfer transistor and that receives a second transfer signal having a second phase in relation to the phase of the driving signal;
a third signal line coupled to the third transfer transistor and that receives a third transfer signal having a third phase in relation to the phase of the drive signal; and
a fourth signal line coupled to the fourth transfer transistor and that receives a fourth transfer signal having a fourth phase in relation to the phase of the driving signal, wherein the first, second, third, and fourth phases are different from one another.

Any one or more of the aspects/embodiments as substantially disclosed herein.

Any one or more of the aspects/embodiments as substantially disclosed herein optionally in combination with any one or more other aspects/embodiments as substantially disclosed herein.

One or more means adapted to perform any one or more of the above aspects/embodiments as substantially disclosed herein.

It is claimed:

1. An imaging device, comprising:
a first pixel including:
a first photoelectric conversion region;
a first transfer transistor coupled to the first photoelectric conversion region; and
a second transfer transistor coupled to the first photoelectric conversion region;
a second pixel adjacent to the first pixel in a first direction and including:
a second photoelectric conversion region;
a third transfer transistor coupled to the second photoelectric conversion region; and
a fourth transfer transistor coupled to the second photoelectric conversion region;
a first signal line coupled to the first transfer transistor and that receives a first transfer signal having a first phase in relation to a phase of a driving signal driving a light source;
a second signal line coupled to the second transfer transistor and that receives a second transfer signal having a second phase in relation to the phase of the driving signal;
a third signal line coupled to the third transfer transistor and that receives a third transfer signal having a third phase in relation to the phase of the driving signal; and
a fourth signal line coupled to the fourth transfer transistor and that receives a fourth transfer signal having a fourth phase in relation to the phase of the driving signal, wherein the first, second, third, and fourth phases are different from one another.

2. The imaging device of claim 1, further comprising:
a third pixel adjacent to the second pixel in the first direction and including:
a third photoelectric conversion region;
a fifth transfer transistor coupled to the third photoelectric conversion region; and
a sixth transfer transistor coupled to the third photoelectric conversion region; and
a fourth pixel adjacent to the third pixel in the first direction and including:
a fourth photoelectric conversion region;
a seventh transfer transistor coupled to the fourth photoelectric conversion region; and
an eighth transfer transistor coupled to the fourth photoelectric conversion region.

3. The imaging device of claim 2, wherein the fifth transfer transistor is coupled to the first signal line, the sixth transfer transistor is coupled to the second signal line, the seventh transfer transistor is coupled to the third signal line, and the eighth transfer transistor is coupled to the fourth signal line.

4. The imaging device of claim 3, further comprising:
a first wiring that couples the first and fifth transfer transistors to the first signal line;
a second wiring that couples the second and sixth transfer transistors to the second signal line;
a third wiring that couples the third and seventh transfer transistors to the third signal line; and
a fourth wiring that couples the fourth and eighth transfer transistors to the fourth signal line.

5. The imaging device of claim 4, wherein the first, second, third, and fourth signal lines extend in a second direction perpendicular to the first direction.

6. The imaging device of claim 5, wherein the first, second, third, and fourth wirings extend in the first direction.

7. The imaging device of claim 6, wherein, in a plan view, each of the first, second, third, and fourth wirings overlaps at least one of the first, second, third, and fourth signal lines.

8. The imaging device of claim 3, wherein, in a plan view, the second and third signal lines are between the first and fourth signal lines.

9. The imaging device of claim 8, wherein, in the plan view, the second and third signal lines are between the second photoelectric conversion region and the third photoelectric conversion region.

10. The imaging device of claim 8, wherein, in the plan view, the first signal line overlaps the first photoelectric conversion region, the second signal line overlaps the second photoelectric conversion region, the third signal line overlaps the third photoelectric conversion region, and the fourth signal line overlaps the fourth photoelectric conversion region.

11. The imaging device of claim 2, further comprising:
a fifth signal line coupled to the fifth transfer transistor and that receives the first transfer signal;
a sixth signal line coupled to the sixth transfer transistor and that receives the second transfer signal;
a seventh signal line coupled to the seventh transfer transistor and that receives the third transfer signal; and
an eighth signal line coupled to the eighth transfer transistor and that receives the fourth transfer signal.

12. The imaging device of claim 11, further comprising:
a first wiring that couples the first transfer transistor to the first signal line;
a second wiring that couples the second transfer transistor to the second signal line;
a third wiring that couples the third transfer transistor to the third signal line; and
a fourth wiring that couples the fourth transfer transistor to the fourth signal line;
a fifth wiring that couples the fifth transfer transistor to the fifth signal line;
a sixth wiring that couples the sixth transfer transistor to the sixth signal line;
a seventh wiring that couples the seventh transfer transistor to the seventh signal line; and
an eighth wiring that couples the eighth transfer transistor to the eighth signal line.

13. The imaging device of claim 12, wherein lengths of the first wiring and the fifth wiring are the same, lengths of the second wiring and the sixth wiring are the same, lengths of the third wiring and the seventh wiring are the same, and lengths of the fourth wiring and the eighth wiring are the same.

14. The imaging device of claim 11, wherein the first, second, third, fourth, fifth, sixth, seventh, and eighth signal lines extend in a second direction perpendicular to the first direction.

15. The imaging device of claim 14, wherein, in a plan view, the second signal line is between the first photoelectric conversion region and the second photoelectric conversion region, the fourth signal line is between the second photoelectric conversion region and third photoelectric conversion region, the sixth signal line is between the third photoelectric conversion region and the fourth photoelectric conversion region.

16. The imaging device of claim 15, wherein, in the plan view, the first signal line overlaps the first photoelectric conversion region, the third signal line overlaps the second photoelectric conversion region, the fifth signal line overlaps the third photoelectric conversion region, and the seventh signal line overlaps the fourth photoelectric conversion region.

17. A system, comprising:
a light source configured to emit a light signal according to a driving signal; and
an imaging device including:
a first pixel including:
a first photoelectric conversion region;
a first transfer transistor coupled to the first photoelectric conversion region; and
a second transfer transistor coupled to the first photoelectric conversion region;
a second pixel adjacent to the first pixel in a first direction and including:
a second photoelectric conversion region;
a third transfer transistor coupled to the second photoelectric conversion region; and
a fourth transfer transistor coupled to the second photoelectric conversion region;
a first signal line coupled to the first transfer transistor and that receives a first transfer signal having a first phase in relation to a phase of the driving signal;
a second signal line coupled to the second transfer transistor and that receives a second transfer signal having a second phase in relation to the phase of the driving signal;
a third signal line coupled to the third transfer transistor and that receives a third transfer signal having a third phase in relation to the phase of the driving signal; and
a fourth signal line coupled to the fourth transfer transistor and that receives a fourth transfer signal having a fourth phase in relation to the phase of the driving signal, wherein the first, second, third, and fourth phases are different from one another.

18. The system of claim 17, wherein the imaging device further comprises:
a third pixel adjacent to the second pixel in the first direction and including:
a third photoelectric conversion region;
a fifth transfer transistor coupled to the third photoelectric conversion region; and
a sixth transfer transistor coupled to the third photoelectric conversion region; and
a fourth pixel adjacent to the third pixel in the first direction and including:
a fourth photoelectric conversion region;
a seventh transfer transistor coupled to the fourth photoelectric conversion region; and
an eighth transfer transistor coupled to the fourth photoelectric conversion region, wherein the fifth transfer transistor is coupled to the first signal line, the sixth transfer transistor is coupled to the second signal line, the seventh transfer transistor is coupled to the third signal line, and the eighth transfer transistor is coupled to the fourth signal line.

19. The system of claim 17, wherein the imaging device further comprises:
a third pixel adjacent to the second pixel in the first direction and including:
a third photoelectric conversion region;
a fifth transfer transistor coupled to the third photoelectric conversion region; and
a sixth transfer transistor coupled to the third photoelectric conversion region; and
a fourth pixel adjacent to the third pixel in the first direction and including:
a fourth photoelectric conversion region;
a seventh transfer transistor coupled to the fourth photoelectric conversion region;
a fifth signal line coupled to the fifth transfer transistor and that receives the first transfer signal;
a sixth signal line coupled to the sixth transfer transistor and that receives the second transfer signal;
a seventh signal line coupled to the seventh transfer transistor and that receives the third transfer signal; and
an eighth signal line coupled to the eighth transfer transistor and that receives the fourth transfer signal.

20. A system, comprising:
a driver that emits a driving signal;
a light source configured to emit light according to the driving signal; and
an imaging device including:
a first pixel including:
a first photoelectric conversion region;
a first transfer transistor coupled to the first photoelectric conversion region; and
a second transfer transistor coupled to the first photoelectric conversion region;
a second pixel adjacent to the first pixel in a first direction and including:
a second photoelectric conversion region;
a third transfer transistor coupled to the second photoelectric conversion region; and
a fourth transfer transistor coupled to the second photoelectric conversion region;
a first signal line coupled to the first transfer transistor and that receives a first transfer signal having a first phase in relation to a phase of the driving signal;
a second signal line coupled to the second transfer transistor and that receives a second transfer signal having a second phase in relation to the phase of the driving signal;
a third signal line coupled to the third transfer transistor and that receives a third transfer signal having a third phase in relation to the phase of the drive signal; and
a fourth signal line coupled to the fourth transfer transistor and that receives a fourth transfer signal having a fourth phase in relation to the phase of the driving signal, wherein the first, second, third, and fourth phases are different from one another.
